(19) United States
(12) Patent Application Publication
(10) Pub. No.: US 2002/0158305 A1
(43) Pub. Date: Oct. 31, 2002

(54) Organic substrate having integrated passive components

(76) Inventors: Sidharth Dalmia, Atlanta, GA (US); Sung Hwan Min, Atlanta, GA (US); Seock Hee Lee, Dunwoody, GA (US); Venkatesh Sundaram, Norcross, GA (US); Farrokh Ayazi, Atlanta, GA (US); George E. White, Marietta, GA (US); Madhavan Swaminathan, Marietta, GA (US); Woopoung Kim, Chamblee, GA (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 09/995,161

(22) Filed: Nov. 26, 2001

Related U.S. Application Data
(60) Provisional application No. 60/259,825, filed on Jan. 5, 2001.

(51) Int. Cl. H01L 29/00

(52) U.S. Cl. 257/531

(57) ABSTRACT

Organic substrates having integrated components and systems and methods for designing and optimizing integrated components for substrates are provided. One embodiment is a computer program embodied in a computer-readable medium for optimizing the design of an integrated inductor in a substrate adapted for use in integrated circuits. Briefly described, one such computer program comprises: logic configured to receive one or more design parameters for a substrate structure in which an inductor is to be integrated, the design parameters specifying at least one of the material characteristics, the physical characteristics, and electrical characteristics of one or more substrate layers and one or more conductor layers comprising the substrate structure; logic configured to receive one or more process parameters associated with a predetermined type of integrated circuit package in which the substrate structure is to be implemented; logic configured to generate a coupled-line model for a plurality of configurations for an integrated inductor, the coupled-line model comprising one or more coupled lines and one or more discontinuities; logic configured to simulate the frequency response of the coupled-line models based on the design parameters and process parameters; and logic configured to determine an optimal configuration for the integrated inductor which satisfies the design parameters and process parameters.

### CROSS-REFERENCE TO RELATED APPLICATION

This application claims priority to copending U.S. provisional application entitled, “High Q-Inductors in MCM-L Technology,” having Application Ser. No. 60/259,825, and filed Jan. 5, 2001, which is entirely incorporated herein by reference.

### TECHNICAL FIELD

The present invention is generally related to integrated circuits and, more particularly, is related to organic substrates having high Q integrated passive components and systems and methods for designing and optimizing high Q integrated passive components for substrates.

### BACKGROUND OF THE INVENTION

Currently, integrated circuit technology is very advanced in the area of discrete surface mount passive components (i.e., resistors, capacitors, and inductors). For example, this technology is very popular in mixed signal designs, such as, for portable wireless electronics and other areas in which digital and radio frequency (RF) circuits are combined into mixed signal modules. However, as the size of electronic devices has decreased, it has become increasingly important for designers to optimize the available real estate on mixed signal chip modules. For instance, in some mixed signal designs, off-chip passive components use more real estate on the boards than the analog and digital signal processing units. Therefore, the development of integrated passive components suitable for integration with printed wiring boards has become increasingly important. By embedding passive components, designers may more efficiently use available real estate on boards.

Existing systems and methods for implementing integrated passive components, however, may be problematic for several reasons. It is important to model the behavior of passive components, which are constituents in critical components such as filters, couplers, phase locked loops, etc., extremely accurately and in a reasonable processing time. The trade off of speed versus accuracy is one that has always plagued designers. Accordingly, it is the goal of the design community to develop solutions that are fast and accurate for modeling integrated components. Besides the difficulty in modeling integrated passives, the presence of severe parasitic effects in silicon-based RF IC's makes the design of high Q reactive components difficult. Q factor refers to the measure of “quality” of a particular frequency response. Therefore, it is advantageous to design integrated passive components having a high Q. Low temperature cofired ceramic (LTCC) technology for multi-chip modules (MCMs) used in RF and wireless systems has provided one solution to this design problem of designing high Q integrated passive components. However, LTCC is an extremely expensive process to implement for consumer applications because of the complexity of the high-temperature fabrication process and/or the expense of the ceramic materials used in the substrates.

Thus, there is a need in the industry for low-cost, integrated substrates for embedding passive components having a high Q factor. Furthermore, there is also a need in the industry for systems and methods for designing and optimizing integrated passive components having a high Q factor.

### SUMMARY OF THE INVENTION

The present invention provides organic substrates having integrated passive components and systems and methods for designing and optimizing integrated passive components for substrates.

One embodiment of the present invention comprises a substrate adapted for use in integrated circuits. Briefly described, one such substrate comprises: a first substrate layer comprising an organic material; a first conductor layer fabricated on an upper surface of the first substrate layer; and an integrated inductor fabricated on an upper surface of the first conductor layer. Another such substrate comprises: a first substrate layer; a first conductor layer fabricated on an upper surface of the first substrate layer; and an integrated inductor fabricated on an upper surface of the first conductor layer, the integrated inductor comprising a micro strip spiral inductor having a strip width between approximately 4 mils and 40 mils and a line spacing between approximately 2 mils and 4 mils. Another such substrate comprises: a first substrate layer; a first conductor layer fabricated on an upper surface of the first substrate layer; and an integrated inductor fabricated on an upper surface of the first conductor layer, the integrated inductor comprising, a coplanar waveguide loop inductor or hollow-ground inductor. Yet another such substrate comprises: a first substrate layer; a first conductor layer fabricated on an upper surface of the first substrate layer; and an integrated inductor fabricated on an upper surface of the first conductor layer, the integrated inductor comprising a microstrip loop inductor.

Another embodiment of the present invention is a method for fabricating a substrate adapted for use in integrated circuits. Briefly described, one such method comprises the steps of fabricating a first substrate layer comprising an organic material; fabricating a first conductor layer on an upper surface of the first substrate layer; and fabricating an integrated inductor on an upper surface of the first conductor layer. Another such method comprises the steps of: fabricating a first substrate layer; fabricating a first conductor layer on an upper surface of the first substrate layer; and fabricating an integrated inductor on an upper surface of the first conductor layer, the integrated inductor comprising a microstrip spiral inductor having a strip width between approximately 4 mils and 40 mils and a line spacing between approximately 2 mils and 4 mils. Another such method comprises the steps of: fabricating a first substrate layer; fabricating a first conductor layer on an upper surface of the first substrate layer; and fabricating an integrated inductor on an upper surface of the first conductor layer, the integrated inductor comprising a coplanar waveguide loop inductor. Yet another such method comprises the steps of: fabricating a first substrate layer; fabricating a first conductor layer on an upper surface of the first substrate layer; and fabricating an integrated inductor on an upper surface of the first conductor layer, the integrated inductor comprising a microstrip loop inductor.

Another embodiment of the present invention is a computer program embodied in a computer-readable medium for optimizing the design of an integrated inductor in a substrate adapted for use in integrated circuits. Briefly described, one such computer program comprises: logic configured to receive one or more design parameters for a substrate structure in which an inductor is to be integrated, the design parameters specifying at least one of the material characteristics, the physical characteristics, and electrical characteristics of one or more substrate layers and one or more conductor layers comprising the substrate structure; logic configured to receive one or more process parameters associated with a predetermined type of integrated circuit package in which the substrate structure is to be implemented; logic configured to generate a coupled-line model for a plurality of configurations for an integrated inductor, the coupled-line model comprising one or more coupled lines and one or more discontinuities; logic configured to simulate the frequency response of the coupled-line models based on the design parameters and process parameters; and logic configured to determine an optimal configuration for the integrated inductor which satisfies the design parameters and process parameters.

The present invention may also be viewed as providing a system for optimizing the design of an integrated inductor in a substrate adapted for use in integrated circuits. Briefly described, one such system comprises: means for receiving one or more design parameters for a substrate structure in which an inductor is to be integrated and one or more process parameters associated with a predetermined type of integrated circuit package in which the substrate structure is to be implemented, the design parameters specifying at least one of the material characteristics, the physical characteristics, and electrical characteristics of one or more substrate layers and one or more conductor layers comprising the substrate structure; means for generating a coupled-line model for a plurality of configurations for an integrated inductor, the coupled-line model comprising one or more coupled lines and one or more discontinuities; means for simulating the frequency response of the coupled-line models based on the design parameters and process parameters; and means for determining an optimal configuration for the integrated inductor which satisfies the design parameters and process parameters.

Briefly described, another such system comprises: logic configured to receive one or more design parameters for a substrate structure in which an inductor is to be integrated, the design parameters specifying at least one of the material characteristics, the physical characteristics, and electrical characteristics of one or more substrate layers and one or more conductor layers comprising the substrate structure; logic configured to receive one or more process parameters associated with a predetermined type of integrated circuit package in which the substrate structure is to be implemented; logic configured to generate a coupled-line model for a plurality of configurations for an integrated inductor, the coupled-line model comprising one or more coupled lines and one or more discontinuities; logic configured to simulate the frequency response of the coupled-line models based on the design parameters and process parameters; logic configured to determine an optimal configuration for the integrated inductor which satisfies the design parameters and process parameters; and a processing device configured to implement the logic.

Other systems, methods, features, and advantages of the present invention will be or become apparent to one with skill in the art upon examination of the following drawings and detailed description. It is intended that all such additional systems, methods, features, and advantages be included within this description, be within the scope of the present invention, and be protected by the accompanying claims.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. Moreover, in the drawings, like reference numerals designate corresponding parts throughout the several views.

FIG. 1 is a cross-sectional view of an embodiment of an organic substrate for integrated passive components according to the present invention.

FIG. 2 is a cross-sectional view of another embodiment of a multi-layer substrate structure for integrated passive components according to the present invention, in which the organic substrate of FIG. 1 may be implemented.

FIG. 3 is a cross-sectional view of another embodiment of a multi-layer substrate structure for integrated passive components according to the present invention, in which the organic substrate of FIG. 1 may be implemented.

FIG. 4 is a block diagram illustrating an implementation of an embodiment of an integrated passive components design/optimization system according to the present invention for designing, modeling, and/or optimizing integrated passive components.

FIG. 5 is a flow chart illustrating the architecture, operation, and/or functionality of the integrated passive components design/optimization system of FIG. 4.

FIG. 6 illustrates an example of an integrated passive component which may be designed, modeled, and/or optimized using the integrated passive components design/optimization system of FIGS. 4 and 5.

FIG. 7 illustrates a coupled-line representation of the integrated passive component of FIG. 6.

FIG. 8 illustrates a mathematical representation of two symmetric, lossless, coupled lines for the integrated passive component represented in FIGS. 6 and 7.

FIG. 9 is a process flow diagram illustrating a low-cost, organic process according to the present invention.

FIG. 10 is a top view of the multi-layer substrate structure of FIG. 2 which illustrates an embodiment of a cascaded microstrip loop inductor according to the present invention.

FIG. 11 is a graph illustrating the normalized reactance versus frequency for the 1-loop, 2-loop, and 3-loop microstrip loop inductors of FIG. 10.

FIG. 12 is a graph illustrating the measured Q-factor versus frequency for the inductors in FIG. 10.

FIG. 13 is a top view of an embodiment of a microstrip loop inductor according to the present invention, which may be implemented in the organic substrates of FIGS. 1-3.

FIG. 14 is a top view of another embodiment of a microstrip loop inductor according to the present invention, which may be implemented in the multi-layer organic substrates of FIGS. 1-3.

FIG. 15 is a top view of another embodiment of a micro strip loop inductor according to the present invention, which may be implemented in the multi-layer organic substrates of FIGS. 1-3.

FIG. 16 is a top view of another embodiment of a microstrip loop inductor according to the present invention, which may be implemented in the multi-layer organic substrates of FIGS. 1-3.

FIG. 17 is a top view of another embodiment of a microstrip loop inductor according to the present invention, which may be implemented in the multi-layer organic substrates of FIGS. 1-3.

FIG. 18 is a Q versus frequency graph comparing the measured data and the model data generated by the integrated passive component design/optimization system of FIGS. 4 and 5 for the microstrip loop inductor of FIG. 17.

FIG. 19 is a self resonant frequency versus frequency graph comparing the measured data and the model data generated by the integrated passive component design/optimization system of FIGS. 4 and 5 for the microstrip loop inductor of FIG. 17.

FIG. 20 is a top view of an embodiment of a microstrip spiral inductor according to the present invention, which may be implemented in the multi-layer organic substrates of FIGS. 1-3.

FIG. 21 is a top view of another embodiment of a microstrip spiral inductor according to the present invention, which may be implemented in the multi-layer organic substrates of FIGS. 1-3.

FIG. 22 is a top view of another embodiment of a microstrip spiral inductor according to the present invention, which may be implemented in the multi-layer organic substrates of FIGS. 1-3.

FIG. 23 is a top view of another embodiment of a micro strip spiral inductor according to the present invention, which may be implemented in the multi-layer organic substrates of FIGS. 1-3.

FIG. 24 is a top view of another embodiment of a microstrip spiral inductor according to the present invention, which may be implemented in the multi-layer organic substrates of FIGS. 1-3.

FIG. 25 is a top view of an embodiment of a CPW loop inductor, which may be implemented in the multi-layer organic substrates of FIGS. 1-3.

FIG. 26 is a top view of another embodiment of a CPW loop inductor, which may be implemented in the multi-layer organic substrates of FIGS. 1-3.

FIG. 27 is a top view of another embodiment of a CPW loop inductor, which may be implemented in the multi-layer organic substrates of FIGS. 1-3.

FIG. 28 is a top view of another embodiment of a CPW loop inductor, which may be implemented in the multi-layer organic substrates of FIGS. 1 and 2.

### DETAILED DESCRIPTION

I. Organic Substrate for Integrated Passive Components

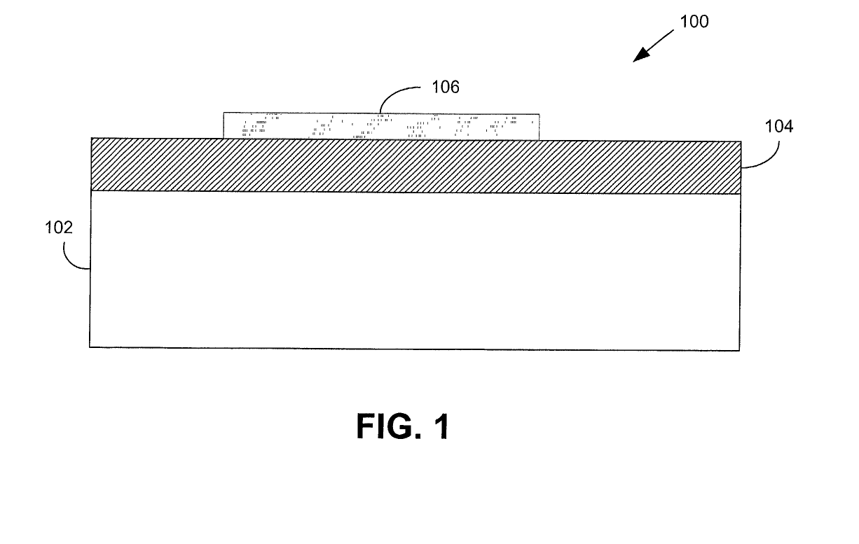

FIG. 1 illustrates a cross-sectional view of an embodiment of an organic substrate 100 according to the present invention. As will be understood with reference to the description that follows, organic substrate 100 enables the design of very low-cost, integrated substrates with integrated inductors having a high Q factor. It will be further appreciated that organic substrate 100 may be implemented in any integrated circuit regardless of the fabrication technology, the particular configuration of the integrated circuit, and/or the intended application of the integrated circuit. For example, organic substrate 100 may be implemented with existing printed wiring board (PWB) technology. Furthermore, organic substrate 100 may also be implemented in cooperation with any of the following, or other, technologies: sequential build-up (SBU) technology, laminated multi-chip module (MCM-L) technology, silicon MCM technology, ceramic MCM technology, low temperature cofired ceramic (LTCC) MCM technology, and System-on-Package (SOP) applications (i.e., voltage controlled oscillators, infrared frequency (IF) and/or radio frequency (RF) bandpass filters, etc.) to name a few.

As shown in FIG. 1, organic substrate 100 comprises an organic substrate layer 102, a conductor layer 104, and an integrated inductor 106. Although illustrated as separate components in FIG. 1, one of ordinary skill in the art will appreciate that integrated inductor 106 comprises the conductor layer 104. Conductor layer 104 may be fabricated on the upper surface of organic substrate layer 102. Integrated inductor 106 may be fabricated on the upper surface of conductor layer 104. As described in more detail below, integrated inductor 106 may be configured with a variety of topologies and/or with a variety of materials. For example, integrated inductor 106 may be configured as a microstrip spiral inductor, a microstrip loop inductor, a coplanar waveguide (CPW) inductor, etc. Integrated inductor 106 may also be configured as a cascaded loop inductor, which comprises one or more microstrip loop inductors cascaded together.

Furthermore, organic substrate layer 102 may comprise any type of organic material. By way of example, organic substrate layer 102 may comprise any of the following, or other, types of organic materials: epoxy-based materials (i.e., Vialux® and Dynavia® manufactured by Dupont Corporation and Shipley Corporation, respectively, etc.), liquid crystalline polymers, resin-coated polymers, etc.

Although the organic substrate 100 illustrated in FIG. 1 has only one organic substrate layer 102 and one conductor layer 104, the organic substrate may be implemented with any number of substrate layers and/or conductor layers. In certain embodiments where multiple substrate layers are implemented, each of the substrate layers may comprise an organic material as described above. In alternative embodiments, such as where organic substrate 100 is implemented in cooperation with other non-organic technologies (i.e., MCM-L, LTCC, etc.), additional substrate layers may not comprise an organic material.

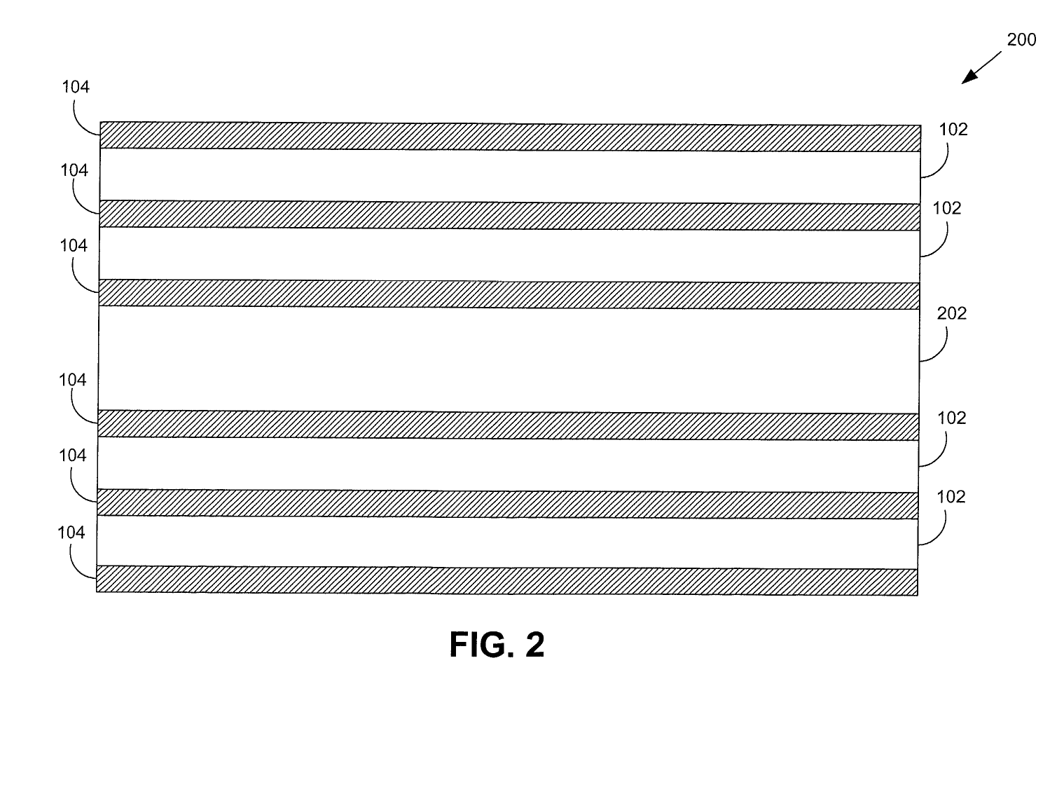

FIG. 2 illustrates a cross-sectional view of an embodiment of an MCM-L substrate structure 200 in which organic substrate 100 may be implemented. Substrate structure 200 comprises six conductor layers 104, four organic substrate layers 102, and another organic substrate layer 202. As with organic substrate 100, substrate structure 200 may be implemented in any integrated circuit regardless of the fabrication technology, the particular configuration of the integrated circuit, and/or the intended application of the integrated circuit. Conductor layers 104 may comprise electroplated copper metal fabricated on the underlying substrate layer. In one embodiment, conductor layers 104 comprise 25 μm electroplated copper metal. One of the conductor layers 104 may be used as the ground reference for the integrated circuits and/or integrated passive components. One of ordinary skill in the art will appreciate that the thickness of the conductor layers may vary depending on design constraints. Furthermore, conductor layers 104 may comprise other types of metals and/or other types of conducting materials and may be fabricated on the substrate layers in various alternative ways.

Organic substrate layers 102 may be configured as described above. By way of example, in the embodiment illustrated in FIG. 2, organic substrate layers 102 comprise 25 μm of an epoxy-based material, such as Vialux 81®, manufactured by Dupont Corporation, and organic substrate layer 202 comprises a 36 mm high temperature laminate, such as FR-406®, manufactured by Nelco Corporation. FR-406® is considered a lossy substrate in that is has a tanδ=0.01 and ε=3.7 at 1 GHz. Vialuxg has a tanδ=0.015 and ε=3.4 at 1GHz. As stated above, the organic substrate layers enable the design of very low-cost integrated components, such as capacitors and inductors.

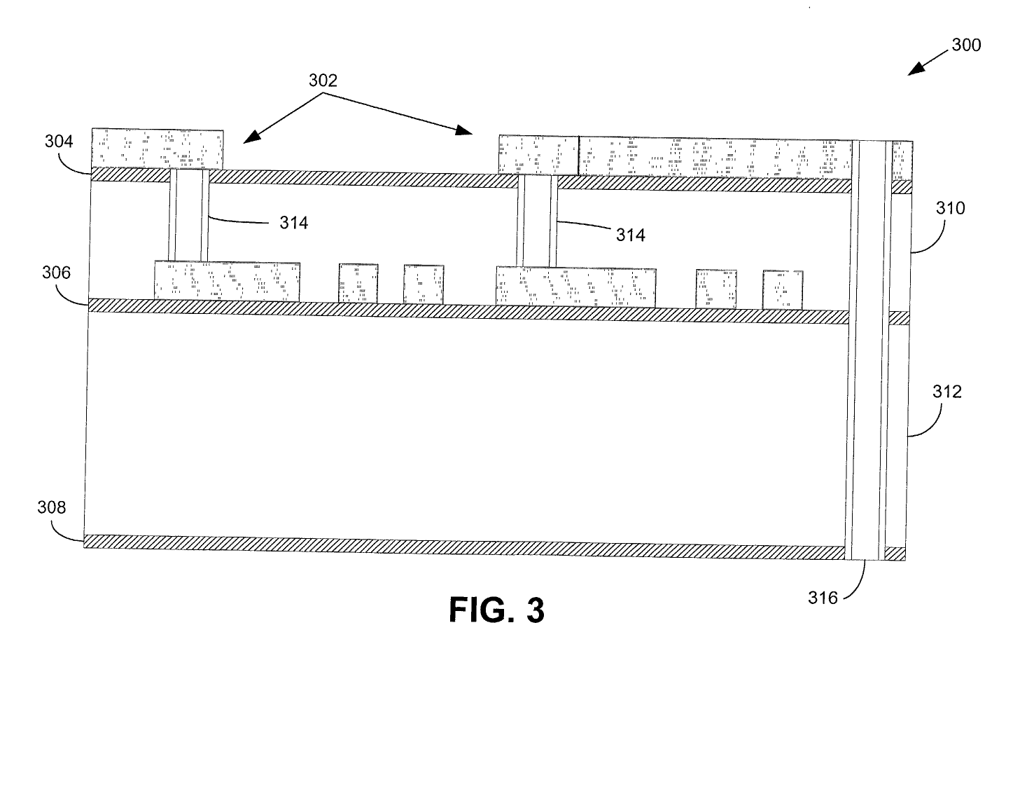

FIG. 3 illustrates another embodiment of a substrate structure 300 for integrated passive components, in which the organic substrate 100 of FIG. 1 may be implemented. Substrate structure 300 comprises a ground plane conductor layer 308 on which a substrate layer 312 is fabricated. A conductor layer 306 is fabricated on the upper surface of the substrate layer 312. Another substrate layer 310 is fabricated on the upper surface of conductor layer 306 and another conductor layer 304 is fabricated on the upper surface of substrate layer 310.

Although the dimensions of the conductor layers and substrate layers may vary depending on design constraints, a particular embodiment will be described with reference to FIG. 3. For example, in cross-section, substrate layer 312 may comprise 28 mm of N4000-13, which is manufactured by Nelco Corp., as the organic core material. Conductor layer 306 may comprise a layer of electroplated copper metal having a thickness of approximately 9-12 μm. Substrate layer 310 may comprise 1 mm thick Vialux®. Conductor layer 304 may comprise a layer of electroplated copper metal having a thickness of approximately 17-20 μm.

As illustrated in FIG. 3, substrate structure 300 is suitable for embedding passive components, such as an integrated inductor 302. In the embodiment illustrated in FIG. 3, integrated inductor 302 is fabricated using conductor layer 304. Furthermore, two portions of the integrated inductor 302 may be connected to each other by way of conductor layer 306 and vias 314. Substrate structure 300 may further comprise a connection 316 which electrically connects integrated inductor 302 to the ground plane represented by conductor layer 308.

It should be noted that organic structure 100 is a completely organic process, thereby making it a low-cost, low-temperature solution. Organic substrate 100 also provides flexibility of layers with arbitrary thickness but similar electrical, thermal, and mechanical processes. However, the lowest cost materials used in the organic process are considered too lossy for existing integrated passive applications and organic processes, which are prone to process variations. The integrated passive component design/optimization system described below, however, allows designers to optimize the design to achieve the desired specifications for integrated passives. As described below in more detail, maximum Q factors in the range of 60-180 in the 1-3 GHz band were obtained for inductors in the range of 1 nH-20 nH. The inductors use aggressive design rules of 2 mil line widths with 2 mil spacings with 2 mil microvia technology. Many designs in the application, optimized for performance in a specific frequency range, use aggressive design features. The flexibility of design rules and the organic process itself make it an ideal base for integration of components for different applications on one common platform.

II. Integrated Passive Component Design/Optimization System

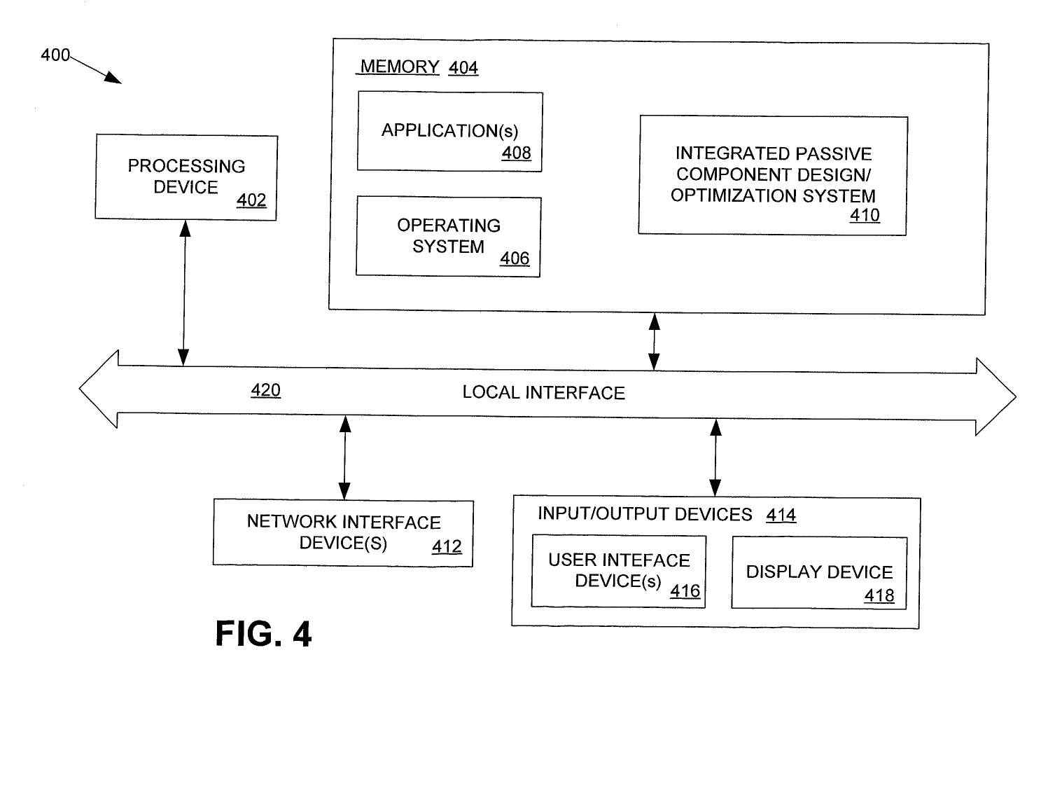

As stated above, organic substrates (i.e., organic substrate 100, substrate structures 200 and 300, etc.) enable the design of very low-cost, integrated substrates with integrated inductors having a high Q factor. FIG. 4 illustrates a representative computing system 400 in which an embodiment of an integrated passive component design/optimization system 410 according to the present invention may be implemented. As described in more detail below, in general, integrated passive component design/optimization system 410 enables a user to design, model, and/or optimize integrated inductors for substrates, such as organic substrate 100.

In general, integrated passive component design/optimization system 410 employs a coupled-line model to model integrated inductors, a segmentation approach to segment the integrated inductor into coupled-line segments and discontinuities, and a simulation tool to compute the impedance matrix of the individual segments and reconstruction of the entire circuit response. Significantly, integrated passive component design/optimization system 410 enables a designer of integrated components to incorporate imperfections, such as non-uniform signal line profiles, varying dielectric constant, surface roughness in different topologies (i.e., CPW, microstrips, and striplines, etc.), and also maintain the frequency dependence of the models. Furthermore, integrated passive component design/optimization system also provides designers of integrated passive components with layouts for specific passive components on a particular substrate, given certain process parameters and specifications.

Integrated passive component design/optimization system 410 may be implemented in software, firmware, hardware, or a combination thereof. In the embodiment illustrated in FIG. 4, integrated passive component design/optimization system 410 is implemented in software, as an executable program, which is executed by a processing device 402. Generally, in terms of hardware architecture, as shown in FIG. 4, computing system 400 comprises a processing device 402, memory 404, one or more network interface devices 512, and one or more input and/or output (I/O) devices 414 interconnected via a local interface 420. System 400 may further comprise additional components not illustrated in FIG. 4.

Referring again to FIG. 4, the various components of system 400 will be described. Local interface 420 may be, for example but not limited to, one or more buses or other wired or wireless connections. The local interface 420 may have additional elements, which are omitted for simplicity, such as controllers, buffers (caches), drivers, repeaters, and receivers, to enable communications. Furthermore, the local interface 420 may include address, control, and/or data connections to enable appropriate communications among the aforementioned components.

Processing device 402 is a hardware device for executing software, particularly that stored in memory 404. Processing device 402 may be any custom-made or commercially-available processor, a central processing unit (CPU), an auxiliary processor among several processors associated with system 400, a semiconductor based microprocessor (in the form of a microchip or chip set), a macroprocessor, or generally any device for executing software instructions.

As illustrated in FIG. 4, memory 404 may comprise an operating system 406, one or more applications 408, and integrated passive component design/optimization system 410. The architecture, operation, and/or functionality of integrated passive component design/optimization system 410 will be described in detail below. Memory 404 may include any one or combination of volatile memory elements (e.g., random access memory (RAM, such as DRAM, SRAM, SDRAM, etc.)) and nonvolatile memory elements (e.g., ROM, hard drive, tape, CDROM, etc.). Memory 404 may incorporate electronic, magnetic, optical, and/or other types of storage media. Furthermore, memory 404 may have a distributed architecture, in which various components are situated remote from one another, but can be accessed by processing device 402.

The software in memory 404 may include one or more separate programs, each of which comprises executable instructions for implementing logical functions. In the example of FIG. 4, the software in memory 404 includes integrated passive component design/optimization system 410 according to the present invention. Memory 404 may further comprise a suitable operating system 406 that controls the execution of other computer programs, such as one or more applications 408 and integrated passive component design/optimization system 410, and provides scheduling, input-output control, file and data management, memory management, and communication control and related services.

Integrated passive component design/optimization system 410 may be a source program, executable program (object code), script, or any other entity comprising a set of instructions to be performed. When implemented as a source program, then the program needs to be translated via a compiler, assembler, interpreter, or the like, which may or may not be included within the memory 404, so as to operate properly in connection with operating system 406. Furthermore, integrated passive component design/optimization system 410 may be written as (a) an object oriented programming language, which has classes of data and methods, or (b) a procedure programming language, which has routines, subroutines, and/or functions, for example but not limited to, C, C++, Pascal, Basic, Fortran, Cobol, Perl, Java, and Ada. In one embodiment, integrated passive component design/optimization system 410 is written as C code and implements commercial mathematical software, such as Matlab®.

Network interface device(s) 418 may be any device configured to facilitate communication between system 400 and a communication network, such as a public or private packet-switched or other data network including the Internet, a circuit switched network, such as the public switched telephone network, a wireless network, an optical network, or any other desired communications infrastructure.

Input/output devices 414 may comprise any device configured to communicate with local interface 420. One of ordinary skill in the art will appreciate that, depending on the configuration of system 400, input/output devices 414 may include any of the following, or other, devices: a user interface device 416 (i.e., a keyboard, a mouse, etc.), a display device 418, such a computer monitor, etc., a serial port, a parallel port, a printer, speakers, a microphone, etc. During operation of system 400, a user may interact with integrated passive component design/optimization system 410 via display device 418 and user interface devices 416.

During operation of system 400, the processing device 402 is configured to execute logic stored within the memory 404, to communicate data to and from the memory 404, and to generally control operations of the system 400 pursuant to the software. Integrated passive component design/optimization system 410 and operating system 406, in whole or in part, but typically the latter, are read by the processing device 402, perhaps buffered within the processing device 402, and then executed.

In embodiments where integrated passive component design/optimization system 410 is implemented in software, as is shown in FIG. 4, integrated passive component design/optimization system 410 may be stored on any computer-readable medium for use by or in connection with any computer related system or method. In the context of this document, a computer-readable medium may be an electronic, magnetic, optical, or other physical device or means that may contain or store a computer program for use by or in connection with a computer-related system or method. Integrated passive component design/optimization system 410 may be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can store, communicate, propagate, or transport the program for use by or in connection with the instruction execution system, apparatus, or device. The computer-readable medium can be, for example but not limited to, an electronic, magnetic, optical, electromagnetic, infrared, or semiconductor system, apparatus, device, or propagation medium. More specific examples (a nonexhaustive list) of the computer-readable medium would include the following: an electrical connection (electronic) having one or more wires, a portable computer diskette (magnetic), a random access memory (RAM) (electronic), a read-only memory (ROM) (electronic), an erasable programmable read-only memory (EPROM, EEPROM, or Flash memory) (electronic), an optical fiber (optical), and a portable compact disc read-only memory (CDROM) (optical). Note that the computer-readable medium could even be paper or another suitable medium upon which the program is printed, as the program can be electronically captured, via for instance optical scanning of the paper or other medium, then compiled, interpreted or otherwise processed in a suitable manner if necessary, and then stored in a computer memory.

In alternative embodiments where integrated passive component design/optimization system 410 is implemented in hardware, integrated passive component design/optimization system 410 may be implemented with any or a combination of the following, or other, technologies: a discrete logic circuit(s) having logic gates for implementing logic functions upon data signals, an application specific integrated circuit (ASIC) having appropriate combinational logic gates, a programmable gate array(s) (PGA), a field programmable gate array (FPGA), etc.

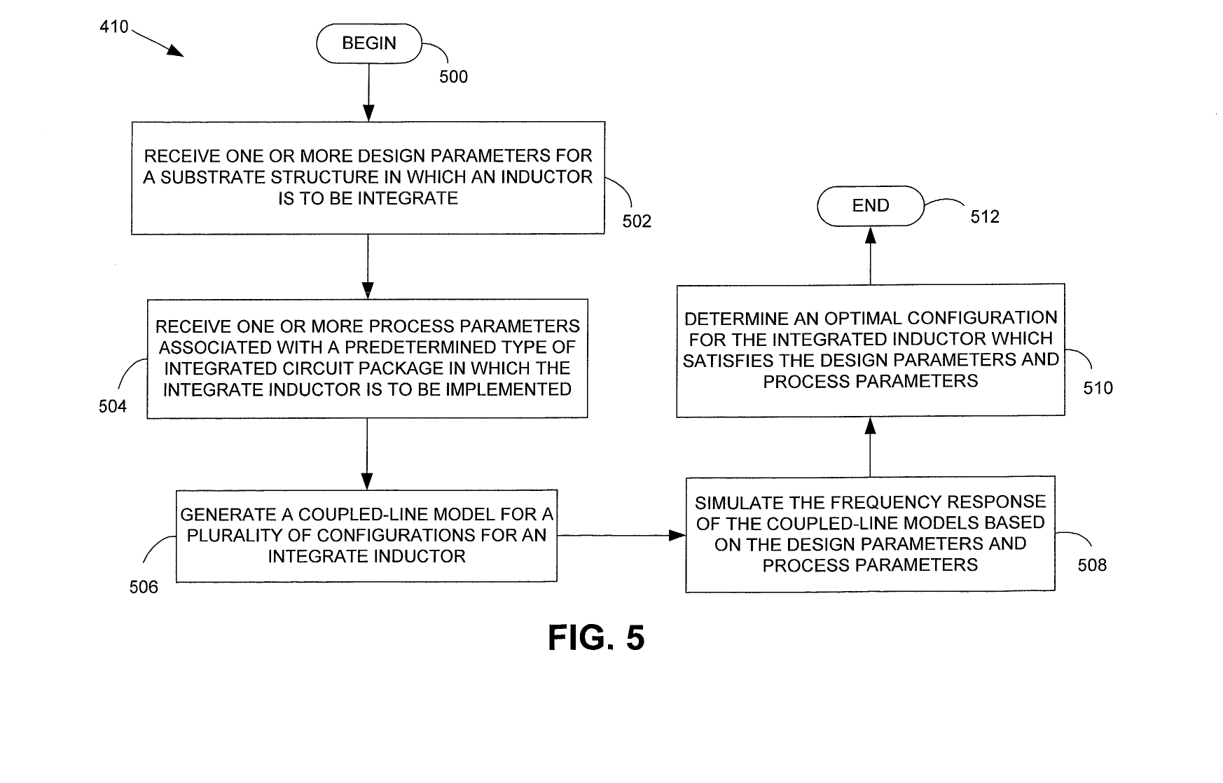

FIG. 5 is a flow chart illustrating the architecture, functionality, and/or operation of an embodiment of integrated passive component design/optimization system 410. Integrated passive component design/optimization system 410 begins at block 500. Integrated passive component design/optimization system 410 may be initiated by a user via an I/O device 414. In alternative embodiments, integrated passive component design/optimization system 410 may be implemented as a function that may be called by operating system 406 and/or an application 408. In alternative embodiments, the functionality of integrated passive component design/optimization system 410 may be seamlessly implemented within an application 408.

Regardless of the manner in which integrated passive component design/optimization system 410 is initiated, at block 502, integrated passive component design/optimization system 410 may receive one or more design parameters for a substrate structure in which a design component, such as an inductor, capacitor, etc., is to be integrated. One of ordinary skill in the art will appreciate that the design parameters may vary depending on various design constraints. For example, the design parameters may specify various characteristics of the substrate structure, such as material characteristics, physical characteristics, (i.e., conductor thickness, etc.) and electrical characteristics of the substrate layers and the conductor layers. At block 504, integrated passive component design/optimization system 410 may receive one or more process parameters (i.e., surface roughness, signal line profile, etc.) associated with a predetermined type of integrated circuit package in which the substrate structure is to be implemented.

Integrated passive component design/optimization system 410 may be configured to receive the information represented at blocks 502 and 504 in a number of ways. In one embodiment, the information is received via an input/output device 414, for example, by a user via a user interface device 416. The information may also be received via a network interface, device 412 or may be accessed directly from memory 404.

At block 506, integrated passive component design/optimization system 410 generates a coupled-line model for a plurality of configurations for an integrated inductor. The coupled-line model of the integrated inductor may comprise one or more coupled lines and one or more discontinuities, such as bends, vias, and steps in width of the trace line. In general, integrated passive component design/optimization system 410 estimates the amount of coupling between integrated passives on the substrate. Integrated passive component design/optimization system 410 models passive structures with the aid of common multi-line parameters. Integrated passive component design/optimization system 410 uses a distributed model, which relates the voltages and currents at the start and end of a multiple coupled line section using impedance and admittance matrices. This modeling approach is explained in S. Dalmia, et al., “Modeling of Embedded RF Passives using Coupled Lines and Scalable Models,” IEEE Electronics, Components and Technology Conference (ECTC), May 2001, which is hereby incorporated by reference in its entirety.

Integrated passive component design/optimization system 410 may be used to model symmetric lines, as well as asymmetric lines. For example, the discontinuities in the integrated inductor, such as bends, vias, cross-overs, and steps in width may be modeled using scalable models. Various scalable models are described in S. H. Min, et al., “Design, Fabrication, Measurement and Modeling of Embedded Inductors in Laminate Technology,” Proc. Of IPACK, July 2001, which is hereby incorporated by reference in its entirety. Scalable models may be used to provide a mapping between the physical and electrical parameters of the discontinuity, which may be represented using rational functions. In general, the mapping may employ interpolation functions. The use of interpolation functions may minimize the number of sampled data points that are required.

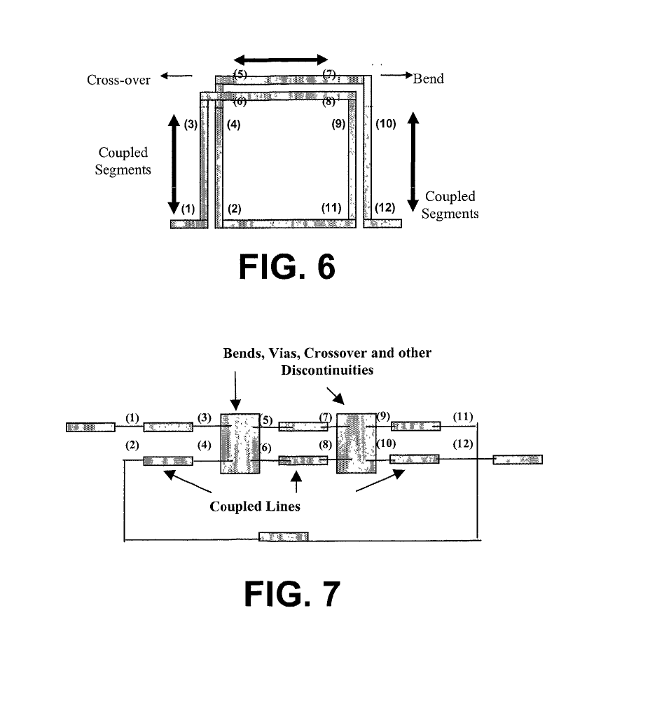

One of ordinary skill in the art will appreciate that the response of integrated passives is dictated by unwanted parasitic effects, which need to modeled accurately. Coupled lines represent an integral part of integrated passives such as filters, couplers, baluns, etc. However, they also represent an integral part of other passives such as spiral and loop inductors and inter-digital capacitors. For purposes of demonstrating the coupled-line model, FIG. 6 illustrates a 1¾ turn spiral inductor. As shown in FIG. 6, the spiral inductor comprises several coupled line sections cascaded with each other through vias, bends, and cross-overs.

FIG. 7 illustrates a cascaded structure representation of the inductor of FIG. 6, which may be derived using a segmentation approach. The segmentation approach is described in S. Dalmia, et al., “Modeling of Embedded RF Passives Using Coupled Lines and Scalable Modes,” IEEE Electronics, Components and Technology Conference (ECTC), May 2001.

The cascaded structure representation comprises a series of coupled lines and discontinuities. The blocks in FIG. 7 represent the discontinuities between the coupled line sections of the inductor. For example, the block between ports 3, 4 and 5, 6 is a crossover and that between 7, 8 and 9, 10 are coupled bends. These discontinuities in the circuit, which may be modeled as electrically short structures at high frequencies, can be modeled using the scalable models described above. The line segments in FIG. 7 represent the multiple coupled line or single uncoupled line sections, which are modeled using the multi-line parameters. One or ordinary skill in the art will appreciate that a multi-mode structure, such as spiral inductors, microstrip loop inductors, and CPW loop inductors, may be segmented as shown in FIG. 7, which enables scalability in the design process. It is worth mentioning that the segmentation approach may be extended to other devices, such as inter-digital capacitors, helical inductors, etc.

Referring again to FIG. 5, at block 506, integrated passive component design/optimization system 410 simulates the frequency response of the coupled-line models based on the design parameters and process parameters. For instance, a set of ‘n’ coupled lines may support ‘n’ independent modes of propagation (called normal modes). Integrated passive component design/optimization system 410 may be configured to simulate the responses of the coupled lines using quasi-transverse electromagnetic (TEM) lines modes of propagation. The accuracy of this approach improves as the ratio of the wavelength to the thickness of the dielectric increases. For example, a two-dimensional electromagnetic solver, such as ANSOFT 2D® provides characteristic mode impedances and propagation constants for lossy and lossless lines. The mode impedances and propagation constants may be used to create a distributed model for the multi-line coupled line sections. At least one advantage of using a distributed model is that it prevents artificial ringing induced by lumped circuit equivalents of the multi-coupled lines and may include frequency dependant parameters.

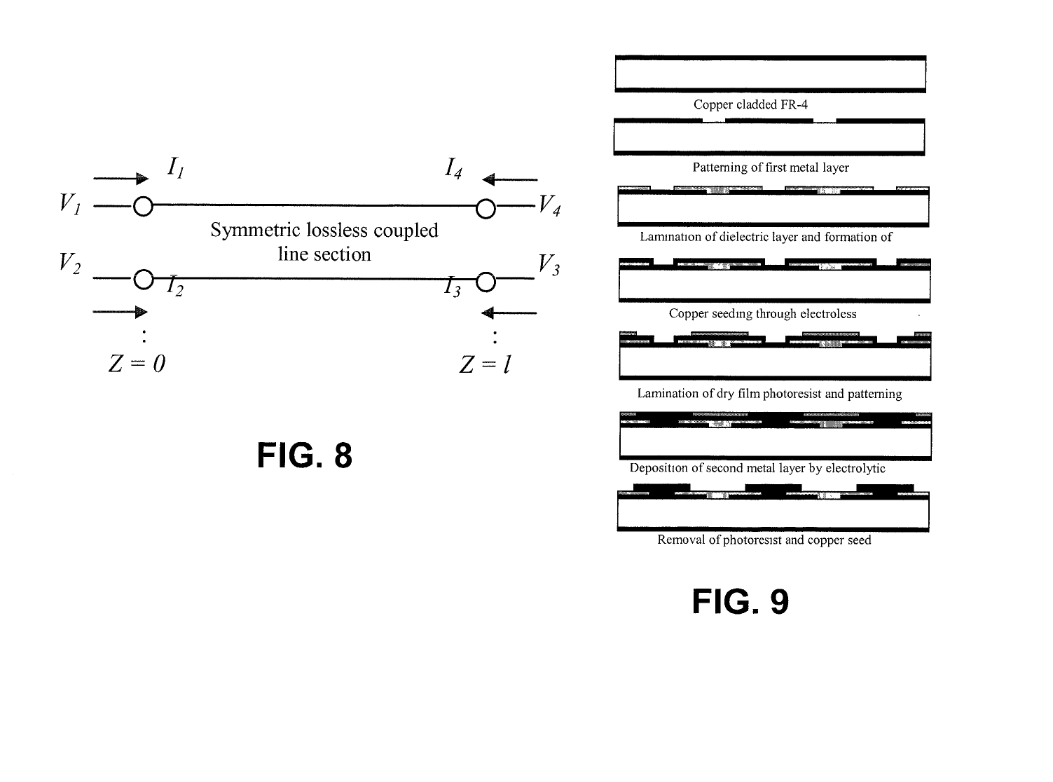

FIG. 8 illustrates a mathematical representation of two symmetric, lossless, coupled lines, which may be implemented by integrated passive component design/optimization system 410 to simulate the frequency response of the coupled-line models. One of ordinary skill in the art will appreciate that voltages and currents on a set of 2 symmetric lossless coupled lines of length, l, shown in FIG. 8 may be obtained from the even-mode impedance (Zₒₑ), odd-mode impedance (Zₒₒ), even-mode propagation constant (βₑ) and odd-mode propagation constant (βₒ) as follows:

$$[ \begin{matrix}{V}_{1} \\ {V}_{2} \\ {V}_{3} \\ {V}_{4}\end{matrix} ] = [ \begin{matrix}{Z}_{11} & {Z}_{12} & {Z}_{13} & {Z}_{14} \\ {Z}_{21} & {Z}_{22} & {Z}_{23} & {Z}_{24} \\ {Z}_{31} & {Z}_{32} & {Z}_{33} & {Z}_{34} \\ {Z}_{41} & {Z}_{42} & {Z}_{43} & {Z}_{44}\end{matrix} ] [ \begin{matrix}{I}_{1} \\ {I}_{2} \\ {I}_{3} \\ {I}_{4}\end{matrix} ]$$

Z₁₁=Z₂₂=Z₃₃=Z₄₄=−j(Zₒₑcot(βₑl)+Zₒₒcot(βₒl))/2

Z₁₂=Z₂₁=Z₃₄=Z₄₃=−j(Zₒₑcot(βₑl)−Zₒₒcot(βₒl))/2

where,

Z₁₃=Z₂₄=Z₃₁=Z₄₂=−j(Zₒₑcsc(βₑl)+Zₒₒcsc(βₒl))/2

Z₁₄=Z₂₃=Z₃₂=Z₄₁=−j(Zₒₑcsc(βₑl)−Zₒₒcsc(βₒl))/2

One of ordinary skill in the art will appreciate that this approach may also be used to model more than a pair of coupled lines. Accordingly, integrated passive component design/optimization system 410 may incorporate the corresponding systems of alternative equations to model more than a pair of coupled lines. One of ordinary skill in the art will further appreciate that integrated passive component design/optimization system 410 may be used to model and simulate frequency responses for asymmetric multi-line lossy-coupled line sections, as described in S. Dalmia, et al., “Modeling of Embedded RF Passives Using Coupled Lines and Scalable Models,” IEEE Electronics, Components and Technology Conference (ECTC), May 2001.

Furthermore, integrated passive component design/optimization system 410 is not limited to homogenous substrates and may be used for multi-layered dielectric substrates. Significantly, integrated passive component design/optimization system 410 enables a designer to optimize the performance of RF passives by varying parameters, such as line width and spacing, for different coupled line sections in the passive design. An example of such an optimization would be in the case of spiral inductors where wider outer turns and narrower inner turns helps reduce ohmic losses in the outer turns and eddy current losses in the inner turns, respectively.

Moreover, integrated passive component design/optimization system 410 may be configured to include other variables, such as the surface roughness of the signal lines, the effect of varying dielectric constants, and non-uniform cross-section in the analysis of the coupled transmission lines. For instance, these variations are typical in laminate technology and/or organic technology, which use a sequential build up process. Tools such as ANSOFT HFSS® may be used to model these non-uniformities, but such tools may be computationally expensive. Tools that utilize emperical equations, such as Agilent's ADS®, reduce computation time, but are limited in terms of bandwidth and need constant revision for new processes and new topologies. Tools such as SONNET, which is a method-of-moments tool, considered optimal for simulating planar components such as inductors, overestimate the loss in the device in coponments with thick conductors.

In these situations, integrated passive component design/optimization system 410 may be configured to extract the R, L, G, and C matrices of non-uniform lines. This function may be performed using a variety of commercial software application, such as ANSOFT 2D®. For instance, if printed circuit boards are cut and then smoothed and polished, one can see the differences in signal line profile when wet-etched, panel plated or pattern plated, which are typical steps in the sequential build up process.

FIG. 9 illustrates the steps of a low cost, organic process according to the present invention, which may be used for fabricating integrated passive components having a high Q. Existing systems, which model these lines using rectangular lines, may overestimate or underestimate the losses, inductances and capacitances of the lines. Integrated passive component design/optimization system 410 may be configured to incorporate the variations in dielectric constant in the computation of the R, L, G, C matrices by observing the empirical equations for the kind of lines under consideration. For example, in the quasi-TEM range, the characteristic impedance of microstrip lines and CPW lines is inversely proportional to \sqrt{(εᵣ+1)/2}. After computing the capacitance matrices, Cₒ,at a frequency, fₒ,with a dielectric constant of εᵣₒ, the C matrices at other frequencies may be be obtained by using the quasi-TEM relationship between the characteristic impedance and dielectric constant such as the one mentioned above. The capacitance matrix, Cₗ at frequency, fₗ, where the dielectric constant is εₗ for microstrip line and CPW lines may be computed by using the following relationship:

cₗ=cₒ×\sqrt{(εᵣₗ+1)/(εᵣₒ+1)}

The L matrices are independent of the dielectric constant. The G matrix at different frequencies can be computed the same way as the capacitance matrix by assuming G is proporational to C. The R matrix involves terms that are dependent on skin-effect, proximity effect, eddy-current losses and effective dielectric constant.

Accordingly, integrated passive component design/optimization system 410 may be configured to incorporate the variations mentioned above for different topologies, such as CPW, microstrip, etc. Once the matrices for the coupled lines and for the scalable functions are obtained they can be cascaded using the segmentation approach described above.

The underlying basis of the segmentation approach is the transformation of the field matching (electric and magnetic fields) along the interface between two regions with higher mode excitations into an equivalent network connection problem using S-, Z-, or Y-matrices. Because Z-matrix characterizations of multiple-coupled lines and planar discontinuities can be obtained as solutions of ordinary differential equations, it becomes computationally efficient to develop a segmentation procedure in terms of Z-parameters.

Referring again to FIG. 5, after simulating the frequency response of the coupled-line models, at block 510, integrated passive component design/optimization system 410 determines one or more optimal configurations for the integrated inductor to be designed, which satisfies the design parameters and process parameters. Integrated passive component design/optimization system 410 may be further configured to provide the optimal configurations to the user via an input/output device 414 and a network interface device 412. Integrated passive component design/optimization system 410 terminates at block 512.

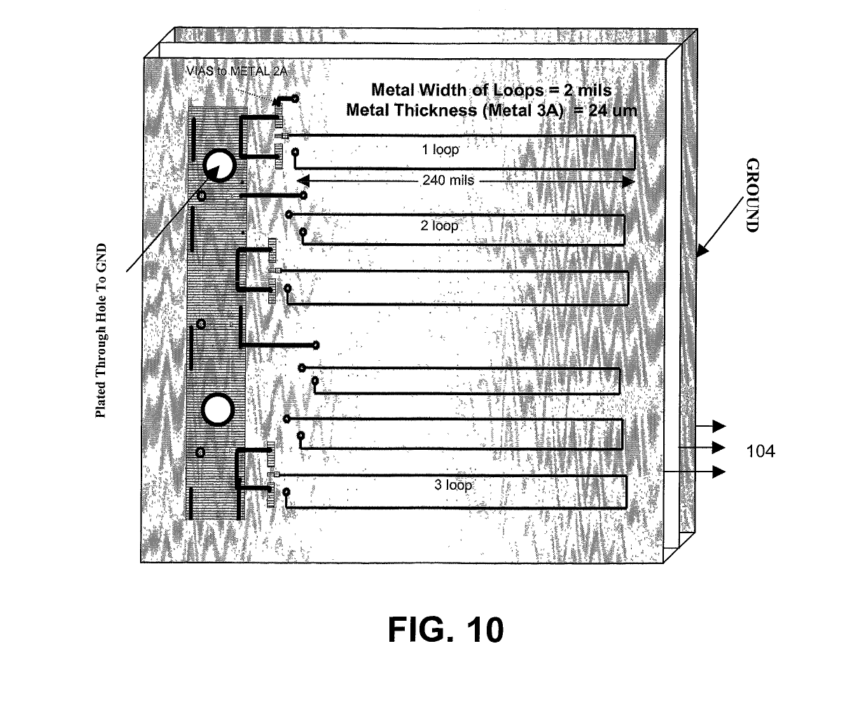

III. Integrated Passive Component Configurations With reference to FIGS. 10-28, designs for various integrated inductors (microstrip loop inductors, cascaded microstrip loop inductors, coplanar waveguide (CPW) loop inductors, and microstrip spiral inductors) will be described. Each of the integrated inductors described may be fabricated on organic substrate 100, substrate structures 200 and 300, or other substrates. Furthermore, it will be appreciated that each of the integrated inductors may be designed using integrated passive component design/optimization system 410.

FIG. 10 is a top view of the multi-layer substrate structure of FIG. 2 which illustrates an embodiment of a cascaded microstrip loop inductor according to the present invention. The microstrip loop inductors are fabricated on the top conductor layer 104. As illustrated in FIG. 10, in one embodiment, the integrated inductor may comprise a single microstrip loop inductor, and in other embodiments, the integrated inductor may comprise two or more microstrip loop inductors cascaded together. As described above with respect to FIG. 3, portions of a single microstrip loop inductor may be connected to each other through the lower conductor layer 104 using vias 314. Furthermore, where multiple microstrip loop inductors are cascaded together, each loop may be connected in this mariner.

Each microstrip loop inductor may comprise a copper trace. One of ordinary skill in the art will appreciate that the configuration of the microstrip loop inductors may vary depending on various design parameters. For example, it may be desirable to limit the microstrip loop inductors to a minimum area on the conductor layers. Thus, the microstrip loop inductors may comprise copper traces of various thickness. In addition, the loops traversed by the copper traces may have varying length, width, and separation. In the embodiment illustrate in FIG. 10, the microstrip loop inductors comprise 2 mm traces, which are approximately 240 mm long.

As stated above, the microstrip loop inductors illustrated in FIG. 10 may be modeled, measured, and/or optimized using integrated passive component design/optimization system 410. Table 1 shows tabulated data for the 1-loop, 2-loop, and 3-loop microstrip inductors illustrated in FIG. 10. A max Q-factor of 103 was obtained for the one loop inductor using 1-port vector network analyzer (VNA) measurements. The VNA was first calibrated using standard SOLT (short-open-load-thru) calibration. Max Q-factors of 38 and 23 were obtained for the 2-loop and 3-loop microstrip inductors respectively.

TABLE 1
Tabulated Data for Microstrip Loop Inductors

| | | | Area | SRF |
|---|---|---|---|---|
| Type | Qmax | Inductance (nH) | (mils²) | (GHz) |
| 1-loop | 103 at 2.2 | 11 nH at 2.2 GHz | 240 * 21 | 3.6 |
| microstrip | GHz | | | |
| 2-loop | 38 at 1.2 | 20.5 nH at 1.2 GHz | 240 * 60 | 2.2 |
| microstrip | GHz | | | |
| 3-loop | 23 at 0.65 | 29 nH at 0.65 GHz | 240 * 86 | 1.6 |
| microstrip | GHz | | | |

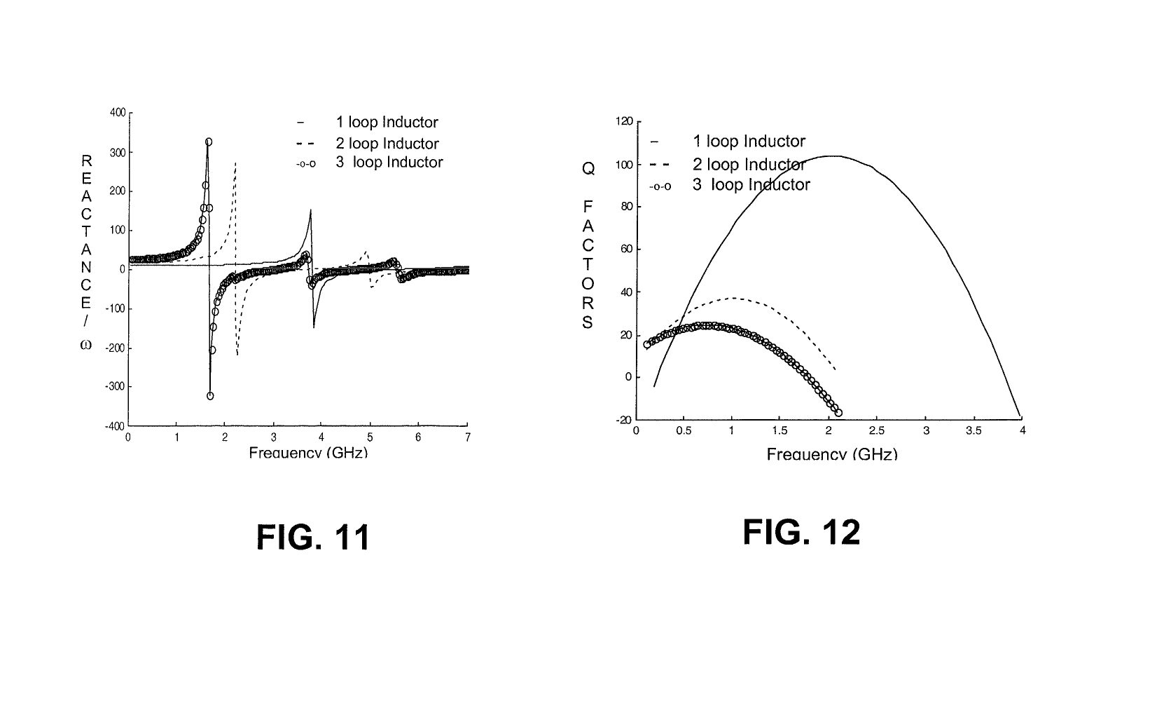

FIG. 11 illustrates the normalized reactance versus frequency for each of the microstrip loop inductors in FIG. 10. FIG. 12 illustrates the measured Q-factor versus frequency for the inductors in FIG. 10.

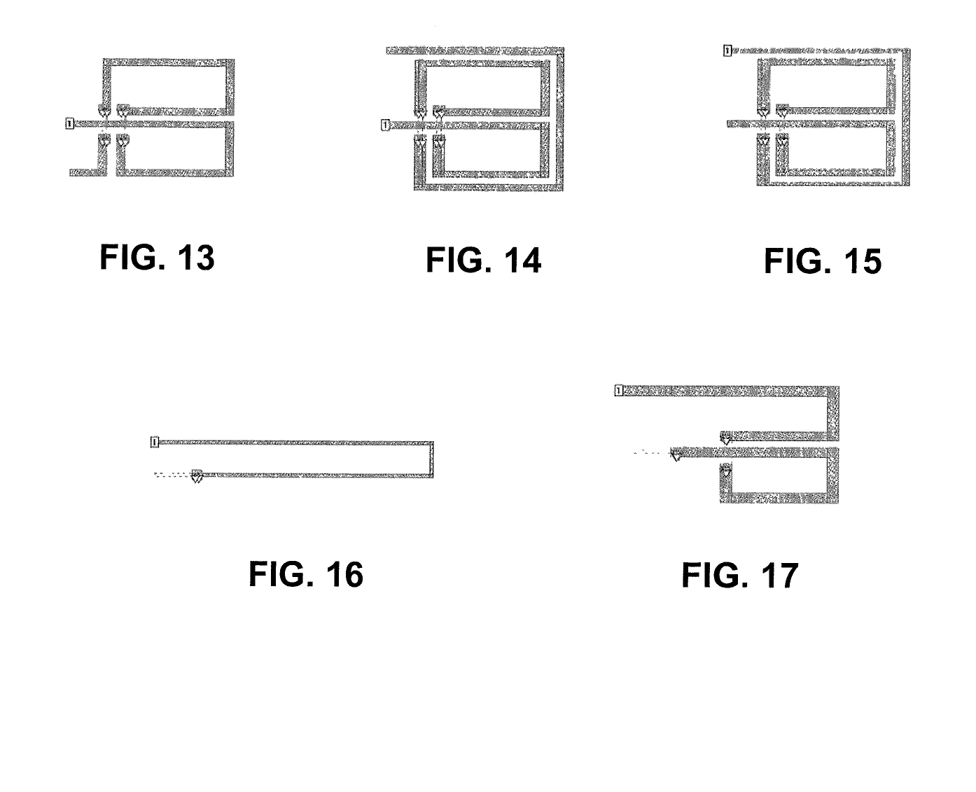

FIGS. 13-17 illustrate various additional configurations for a microstrip loop inductor according to the present invention. FIG. 13 illustrates a microstrip loop inductor comprising two cascaded loops. The microstrip loop inductor has a line width of approximately 4 mil and an area of approximately 3.5mm².

FIG. 14 illustrates a microstrip loop inductor comprising three cascaded loops.

The microstrip loop inductor has a first portion with a line width of approximately 4 mil, a second portion with a line width of approximately 8 mil, and an area of approximately 4 mm².

FIG. 15 illustrates a microstrip loop inductor comprising three cascaded loops. The microstrip loop inductor has a first portion with a line width of approximately 4 mil, a second portion with a line width of approximately 2 mil, and an area of approximately 4 mm².

FIG. 16 illustrates a microstrip loop inductor comprising a single loop. The micro strip loop inductor has a line width of approximately 2 mil and an area of approximately 3.5 mm².

FIG. 17 illustrates a micro strip loop inductor comprising two cascaded loops. The microstrip loop inductor has a line width of approximately 6 mil and an area of approximately 4.3 mm².

Table 2 shows the measured data for the microstrip loop inductors illustrated in FIGS. 13-17. The data was collected using Agilent's 8720ES Vector Network Analyzer (VNA). The data was collected using a 500 μm pitch Cascade Microtech GSG probe after using a 1-port Short-Open-Load calibration with an averaging factor of 32 and 1601 points for bandwidths of 2 GHz.

TABLE 2
Tabulated Data for Microstrip Loop Inductors in FIGS. 13-17

| Inductor | Qmax | Inductance (nH) | Area (mils²) | SRF (GHz) |
|---|---|---|---|---|
| | 85 at 2.2 GHz | 10.2 nH | 3.5 mm² | 5 |
| | 80 at 1 GHz | 15 nH | 4 mm² | 3.2 |
| | 70 at 1 GHz | 17 nH | 4 mm² | 3 |
| | 90 at 2.4 GHz | 7.68 nH | 3.5 mm² | 7.2 |
| | 110 at 2.1 GHz | 7.8 nH | 4.3 mm² | 6 |

As shown in Table 2, the microstrip loop inductors of FIGS. 13, 16, and 17 are well-suited for applications around 2 GHz and the microstrip loop inductors of FIGS. 14 and 15 are well-suited for applications around 1 GHz.

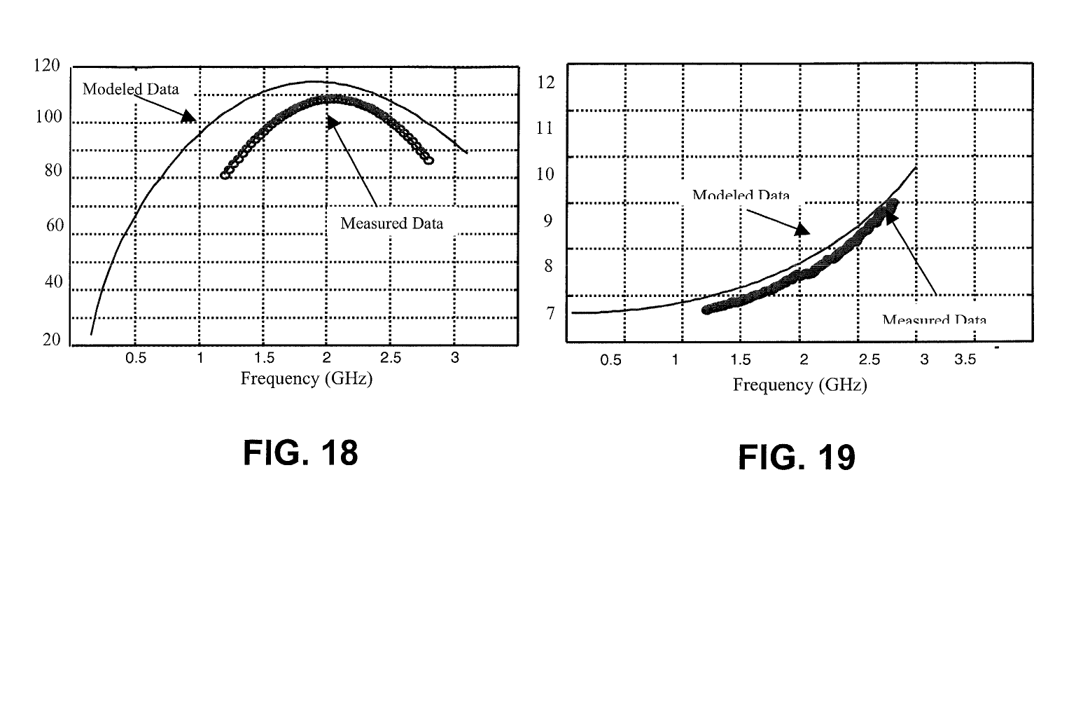

FIGS. 18 and 19 compare the measured data and the model data generated by integrated passive component design/optimization system 410 for the microstrip loop inductor illustrated in FIG. 17. It should be noted that no scalable models for bends and vias were incorporated for simplicity. Instead, the bends and vias were treated as short circuits.

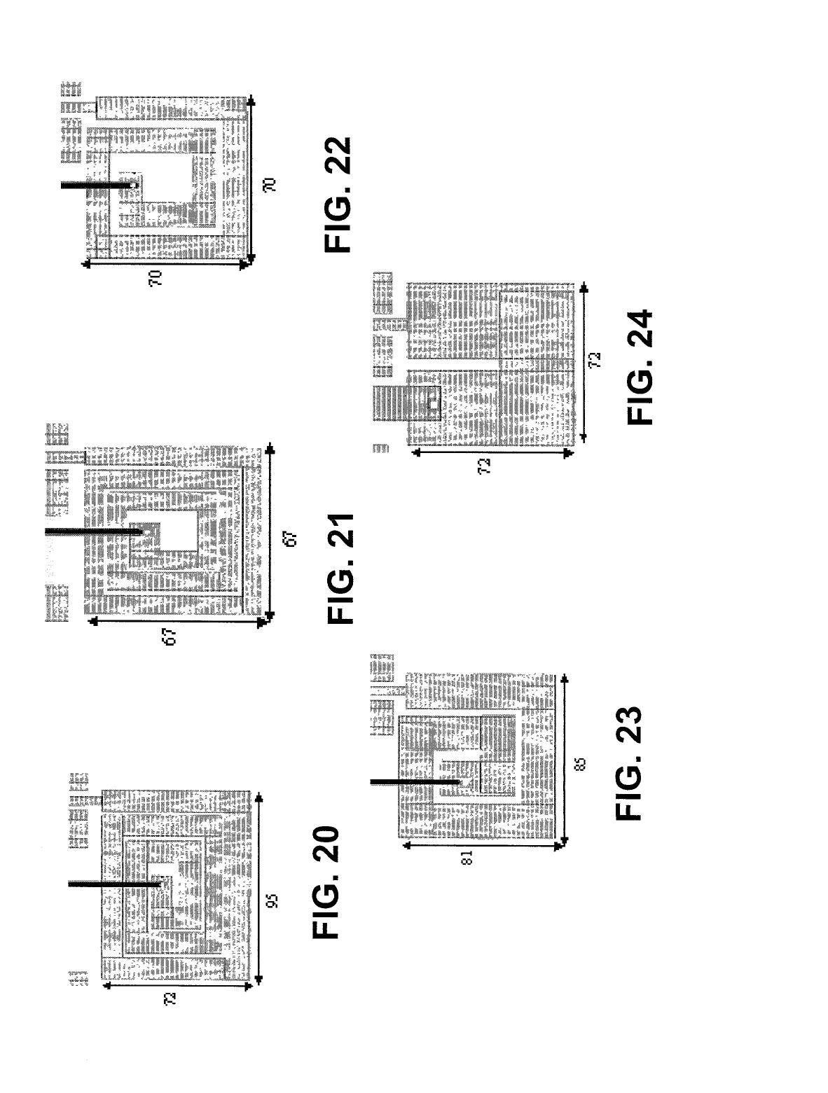

FIGS. 20-24 illustrate various configurations for wide-strip, narrow-spacing microstrip spiral inductors according to the present invention. For instance, each of the inductors has a strip width between approximately 4 mil and 40 mil and a line spacing between approximately 2 mil and approximately 4 mil. Narrow-strip, narrow-spacing spiral inductors provide high inductances, but exhibit low Q factors because of the associated skin-effect losses, eddy current losses and proximity effect losses. With a ground-to-signal spacing of 29 mils, the associated inductances that can be obtained from multi-turn narrow-strip, narrow-spacing spiral inductors is far too much than what is required for certain applications, such as 2 GHz frequency applications.

Wide-strip, narrow-spacing spiral inductors provide lower inductances and suffer from eddy current and proximity effects; however, the wide strips and the associated metal thickness (approximately 17-20 μm) together help reduce the skin-effect and DC resistance significantly. Maintaining the spacing narrow (approximately 2-4 mm) helps keep the size of the inductors small and also helps increase the positive mutual inductance between lines. The capacitance to ground increases due to the increased widths, thereby reducing the effective inductances and lowering the SRF. Nonetheless, integrated passive component design/optimization system 410 enables the design and optimization of multi-turn spiral inductors having sufficient inductances (approximately 1 nH-10 nH) with maximum Q factors at approximately 1 GHz and 2 GHz and an SRF>5 GHz.

FIG. 20 illustrates a three-turn microstrip spiral inductor. The microstrip spiral inductor has a line width of approximately 10 mil, a line spacing of approximately 2 mil, and an area of approximately 4.4 mm².

FIG. 21 illustrates a three-turn microstrip spiral inductor. The microstrip spiral inductor has a line width of approximately 7 mil, a line spacing of approximately 2 mm, and an area of approximately 3.1 mm².

FIG. 22 illustrates a two-turn microstrip spiral inductor. The microstrip spiral inductor has a line width of approximately 10 mil, a line spacing of approximately 4 mm, and an area of approximately 3.2 mm².

FIG. 23 illustrates a two-turn microstrip spiral inductor. The microstrip spiral inductor has a line width of approximately 18 mil, a line spacing of approximately 4 mil, and an area of approximately 4.5 mm².

FIG. 24 illustrates a one-turn microstrip spiral inductor. The microstrip spiral inductor has a line width of approximately 34 mil, a line spacing of approximately 4 mil, and an area of approximately 3.2 mm².

Table 3 shows the measured data for the microstrip spiral inductors illustrated in FIGS. 20-24.

TABLE 3
Tabulated Data for Microstrip Spiral Inductors in FIGS. 20-24

| Inductor | Qmax | Inductance (nH) | Area (mils²) | SRF (GHz) |
|---|---|---|---|---|
| | 80 at 1.5 GHz | 12 nH | 4.4 mm² | 3.9 |
| | 100 at 1.0 GHz | 12 nH | 3.1 mm² | 3.2 |
| | 100 at 2.0 GHz | 7 nH | 3.2 mm² | 6.8 |
| | 110 at 2.0 GHz | 5.2 nH | 4.5 mm² | 7 |
| | 170 at 2.4 GHz | 1.5 nH | 3.2 mm² | 8.5 |

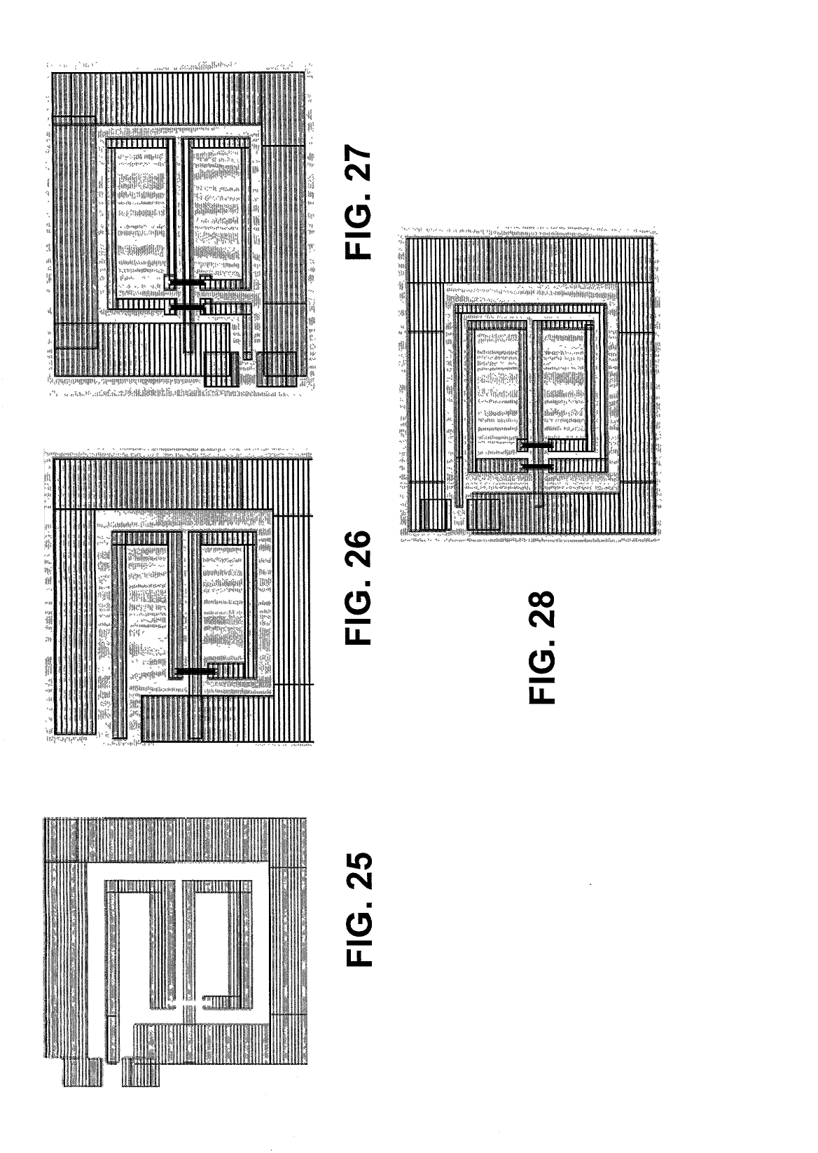

FIGS. 25-28 illustrate various configurations for coplanar waveguide (CPW) loop inductors according to the present invention. As illustrated in FIGS. 25-28, the CPW loop inductors may be CPW/hollow-ground loop inductors. Unlike the microstip loop inductors, the ground or reference for the devices are the wide ground rings around the devices themselves, as shown in FIGS. 25-28. Although this eliminates the need for backside connections, it does increase the area of the device. The CPW topology ensures the proximity of the ground since the structure and ground are co-planar and also prevent the current-crowding on the ground planes by forcing the currents to flow around the device on the larger area co-planar ground. The same procedure was used as described above, to measure the max Q factor and frequency, the effective inductance, area, and SRF for each of the inductors of FIGS. 25-28. The measured results yielded a Q factor almost double for the CPW type inductors compared to the microstrip inductors. Table 4 shows the measured data for the coplanar waveguide inductors illustrated in FIGS. 25-28.

TABLE 4
Tabulated Data for Coplanar Waveguide
Loop Inductors in FIGS. 25-28

| | | Effective | | |
|---|---|---|---|---|
| | Max Q | Inductance | Area | SRF |
| Inductor | (at Freq [GHz]) | (nH) | mm² | GHz |
| | Q = 170 at 2.2 | L = 4.8 | 9 | 5.5 |
| | Q = 150 at 1.9 | L = 5.8 | 9 | 5.2 |
| | Q = 110 at 1.8 | L = 8.8 | 9.5 | 5 |
| | Q = 70 at 1.8 | L = 14 | 9.5 | 5 |

It should be emphasized that the above-described embodiments, particularly, any “described” embodiments, are merely possible examples of implementations, merely set forth for a clear understanding of the principles of the invention. Many variations and modifications may be made to the above-described embodiment(s) of the invention without departing substantially from the spirit and principles of the invention. All such modifications and variations are intended to be included herein within the scope of this disclosure and protected by the following claims.

Therefore, having thus described the invention, at least the following is claimed:

1. A substrate adapted for use in integrated circuits, the substrate comprising:
a first substrate layer comprising an organic material;
a first conductor layer fabricated on an upper surface of the first substrate layer; and
an integrated inductor fabricated on an upper surface of the first conductor layer.

2. The substrate of claim 1, wherein the integrated inductor comprises a spiral inductor.

3. The substrate of claim 1, wherein the integrated inductor comprises a microstrip loop inductor.

4. The substrate of claim 1, wherein the organic material is at least one of an epoxy-based material and a liquid crystalline polymer.

5. The substrate of claim 1, further comprising a second conductor layer fabricated on a lower surface of the first substrate layer, the second conductor layer adapted as a ground plane for the first conductor layer.

6. The substrate of claim 1, wherein the integrated inductor and the first conductor layer are configured in a coplanar waveguide arrangement.

7. The substrate of claim 1, wherein the integrated inductor comprises a cascaded loop inductor comprising one or more microstrip loop inductors cascaded together.

8. The substrate of claim 1, further comprising a second conductor layer fabricated on a lower surface of the first substrate layer, wherein two points of the integrated inductor are electrically connected through a via connected to the second conductor layer.

9. The substrate of claim 8, further comprising:
a second substrate layer fabricated on a lower surface of the second conductor layer; and
a third conductor layer fabricated on a lower surface of the second substrate layer.

10. The substrate of claim 9, wherein the second substrate layer comprises an organic material.

11. The substrate of claim 10, wherein the organic material is at least one of an epoxy-based material and a liquid crystalline polymer.

12. A method for fabricating a substrate adapted for use in integrated circuits, the method comprising the steps of:
fabricating a first substrate layer comprising an organic material;
fabricating a first conductor layer on an upper surface of the first substrate layer; and
fabricating an integrated inductor on an upper surface of the first conductor layer.

13. The method of claim 12, wherein the integrated inductor comprises a spiral inductor.

14. The method of claim 12, wherein the integrated inductor comprises a microstrip loop inductor.

15. The method of claim 12, wherein the organic material is at least one of an epoxy-based material, a liquid crystalline polymer, and a resin-coated polymer.

16. The method of claim 12, further comprising the step of fabricating a second conductor layer on a lower surface of the first substrate layer, the second conductor layer adapted as a ground plane for the first conductor layer.

17. The method of claim 12, wherein the steps of fabricating an integrated inductor and a first conductor layer comprise fabricating the integrated inductor as a coplanar waveguide inductor.

18. The method of claim 12, wherein the step of fabricating an integrated inductor further comprises cascading one or more microstrip loop inductors together.

19. The method of claim 12, further comprising the step of fabricating a second conductor layer on a lower surface of the first substrate layer, and wherein the step of fabricating an integrated inductor comprises electrically connecting two points of the integrated inductor through a via connected to the second conductor layer.

20. The method of claim 12, further comprising the steps of:
fabricating a second substrate layer on a lower surface of the second conductor layer; and
fabricating a third conductor layer on a lower surface of the second substrate layer.

21. The method of claim 20, wherein the second substrate layer comprises an organic material.

22. The method of claim 21, wherein the organic material is at least one of an epoxy-based material and a liquid crystalline polymer.

23. A substrate adapted for use in integrated circuits, the substrate comprising:
a first substrate layer;
a first conductor layer fabricated on an upper surface of the first substrate layer; and
an integrated inductor fabricated on an upper surface of the first conductor layer, the integrated inductor comprising a microstrip spiral inductor having a strip width between approximately 4 mils and 40 mils and a line spacing between approximately 2 mils and 4 mils.

24. The substrate of claim 23, wherein the first substrate layer comprises an organic material.

25. The substrate of claim 24, wherein the organic material is at least one of an epoxy-based material and a liquid crystalline polymer.

26. The substrate of claim 23, wherein the line width, line spacing, and number of turns for the microstrip spiral inductor are configured to optimize at least one of a frequency for a maximum Q factor, an effective inductance, and a self resonant frequency.

27. The substrate of claim 23, wherein the microstrip spiral inductor comprises a three-turn microstrip.

28. The substrate of claim 27, wherein the microstrip spiral inductor has a line width of approximately 10 mils, a line spacing of approximately 2 mils, and an area of approximately 4.4 millimeters².

29. The substrate of claim 28, wherein the microstrip spiral inductor has an effective inductance of approximately 12 nH at approximately 1.5 GHz, a maximum Q factor of approximately 80 at approximately 1.5 GHz, and a self resonating frequency of approximately 3.9 GHz.

30. The substrate of claim 27, wherein the microstrip spiral inductor has a line width of approximately 7 mils, a line spacing of approximately 2 mils, and an area of approximately 3.1 millimeters².

31. The substrate of claim 30, wherein the microstrip spiral inductor has an effective inductance of approximately 12 nH at approximately 1 GHz, a maximum Q factor of approximately 100 at approximately 1 GHz, and a self resonating frequency of approximately 3.2 GHz.

32. The substrate of claim 23, wherein the microstrip spiral inductor comprises a two-turn microstrip.

33. The substrate of claim 32, wherein the microstrip spiral inductor has a line width of approximately 10 mils, a line spacing of approximately 4 mils, and an area of approximately 3.2 millimeters².

34. The substrate of claim 33, wherein the microstrip spiral inductor has an effective inductance of approximately 7 nH at approximately 2 GHz, a maximum Q factor of approximately 100 at approximately 2 GHz, and a self resonating frequency of approximately 6.8 GHz.

35. The substrate of claim 32, wherein the microstrip spiral inductor has a line width of approximately 18 mils, a line spacing of approximately 4 mils, and an area of approximately 4.5 millimeters².

36. The substrate of claim 35, wherein the microstrip spiral inductor has an effective inductance of approximately 5.2 nH at approximately 2 GHz, a maximum Q factor of approximately 110 at approximately 2 GHz, and a self resonating frequency of approximately 7 GHz.

37. The substrate of claim 23, wherein the microstrip spiral inductor comprises a one-turn microstrip.

38. The substrate of claim 37, wherein the microstrip spiral inductor has a line width of approximately 34 mils, a line spacing of approximately 4 mils, and an area of approximately 3.2 millimeters².

39. The substrate of claim 38, wherein the microstrip spiral inductor has an effective inductance of approximately 1.5 nH at approximately 2.4 GHz, a maximum Q factor of approximately 170 at approximately 2.4 GHz, and a self resonating frequency of approximately 8.5 GHz.

40. A substrate adapted for use in integrated circuits, the substrate comprising:
a first substrate layer;
a first conductor layer fabricated on an upper surface of the first substrate layer; and
an integrated inductor fabricated on an upper surface of the first conductor layer, the integrated inductor comprising a coplanar waveguide loop inductor.

41. The substrate of claim 40, wherein the first substrate layer comprises an organic material.

42. The substrate of claim 41, wherein the organic material is at least one of an epoxy-based material and a liquid crystalline polymer.

43. The substrate of claim 40, wherein the number of loops comprising the coplanar waveguide loop inductor is configured to optimize at least one of a frequency for a maximum Q factor, an effective inductance, and a self resonant frequency.

44. The substrate of claim 40, wherein the coplanar waveguide loop inductor comprises hollow-ground coplanar waveguide loop inductor.

45. A substrate adapted for use in integrated circuits, the substrate comprising:
a first substrate layer;
a first conductor layer fabricated on an upper surface of the first substrate layer; and
an integrated inductor fabricated on an upper surface of the first conductor layer, the integrated inductor comprising a microstrip loop inductor.

46. The substrate of claim 45, wherein the configuration of the microstrip loop inductor is designed to optimize at least one of a frequency for a maximum Q factor, an effective inductance, and a self resonant frequency.

47. The substrate of claim 45, wherein the number of loops and the line width of the microstrip loop inductor are designed to optimize at least one of a frequency for a maximum Q factor, an effective inductance, and a self resonant frequency.

48. The substrate of claim 45, wherein the microstrip loop inductor comprises a single loop having a line width of approximately 2 mils and an area of approximately 3.5 millimeters².

49. The substrate of claim 48, wherein the microstrip loop inductor has an effective inductance of approximately 7.7 nH, a maximum Q factor of approximately 90 at approximately 2.4 GHz, and a self resonating frequency of approximately 7.2 GHz.

50. The substrate of claim 45, wherein the microstrip loop inductor comprises two cascaded loops.

51. The substrate of claim 50, wherein the microstrip loop inductor has a line width of approximately 6 mils and an area of approximately 4.3 millimeters².

52. The substrate of claim 51, wherein the microstrip loop inductor has an effective inductance of approximately 7.8 nH, a maximum Q factor of approximately 110 at approximately 2.1 GHz, and a self resonating frequency of approximately 6 GHz.

53. The substrate of claim 52, wherein the microstrip loop inductor has a line width of approximately 4 mils and an area of approximately 3.5 millimeters².

54. The substrate of claim 50, wherein the microstrip loop inductor has an effective inductance of approximately 10.2 nH, a maximum Q factor of approximately 85 at approximately 2.2 GHz, and a self resonating frequency of approximately 5 GHz.

55. The substrate of claim 45, wherein the microstip loop inductor comprises three cascaded loops.

56. The substrate of claim 55, wherein the microstrip loop inductor has an area of approximately 4 millimeters² and a first portion of the microstrip loop inductor has a line width of approximately 4 mils and a second portion of the microstrip loop inductor has a line width of approximately 8 mils.

57. The substrate of claim 56, wherein the microstrip loop inductor has an effective inductance of approximately 15 nH, a maximum Q factor of approximately 80 at approximately 1 GHz, and a self resonating frequency of approximately 3.2 GHz.

58. The substrate of claim 55, wherein the microstrip loop inductor has an area of approximately 4 millimeters² and a first portion of the microstrip loop inductor has a line width of approximately 4 mils and a second portion of the microstrip loop inductor has a line width of approximately 2 mils.

59. The substrate of claim 58, wherein the microstrip loop inductor has an effective inductance of approximately 17 nH, a maximum Q factor of approximately 70 at approximately 1 GHz, and a self resonating frequency of approximately 3 GHz.

60. A method for fabricating a substrate having integrated components and adapted for use in integrated circuits, the method comprising the steps of:
fabricating a first substrate layer;
fabricating a first conductor layer on an upper surface of the first substrate layer; and
fabricating an integrated inductor on an upper surface of the first conductor layer, the integrated inductor comprising a microstrip spiral inductor having a strip width between approximately 4 mils and 40 mils and a line spacing between approximately 2 mils and 4 mils.

61. The method of claim 60 , wherein the first substrate layer comprises an organic material.

62. The method of claim 61, wherein the organic material is at least one of an epoxy-based material and a liquid crystalline polymer.

63. The method of claim 60, wherein the step of fabricating an integrated inductor further comprises configuring at least one of the line width, line spacing, and number of turns for the microstrip spiral inductor to optimize at least one of a frequency for a maximum Q factor, an effective inductance, and a self resonant frequency.

64. The method of claim 60, wherein the microstrip spiral inductor comprises a three-turn microstrip.

65. The method of claim 64, wherein the microstrip spiral inductor has a line width of approximately 10 mils, a line spacing of approximately 2 mils, and an area of approximately 4.4 millimeters².

66. The method of claim 65, wherein the microstrip spiral inductor has an effective inductance of approximately 12 nH at approximately 1.5 GHz, a maximum Q factor of approximately 80 at approximately 1.5 GHz, and a self resonating frequency of approximately 3.9 GHz.

67. The method of claim 64, wherein the microstrip spiral inductor has a line width of approximately 7 mils, a line spacing of approximately 2 mils, and an area of approximately 3.1 millimeters².

68. The method of claim 67, wherein the microstrip spiral inductor has an effective inductance of approximately 12 nH at approximately 1 GHz, a maximum Q factor of approximately 100 at approximately 1 GHz, and a self resonating frequency of approximately 3.2 GHz.

69. The method of claim 60, wherein the microstrip spiral inductor comprises a two-turn microstrip.

70. The method of claim 68, wherein the microstrip spiral inductor has a line width of approximately 10 mils, a line spacing of approximately 4 mils, and an area of approximately 3.2 millimeters².

71. The method of claim 70, wherein the microstrip spiral inductor has an effective inductance of approximately 7 nH at approximately 2 GHz, a maximum Q factor of approximately 100 at approximately 2 GHz, and a self resonating frequency of approximately 6.8 GHz.

72. The method of claim 69, wherein the microstrip spiral inductor has a line width of approximately 18 mils, a line spacing of approximately 4 mils, and an area of approximately 4.5 millimeters².

73. The method of claim 72, wherein the microstrip spiral inductor has an effective inductance of approximately 5.2 nH at approximately 2 GHz, a maximum Q factor of approximately 110 at approximately 2 GHz, and a self resonating frequency of approximately 7 GHz.

74. The method of claim 60, wherein the microstrip spiral inductor comprises a one-turn microstrip.

75. The method of claim 74, wherein the microstrip spiral inductor has a line width of approximately 34 mils, a line spacing of approximately 4 mils, and an area of approximately 3.2 millimeters².

76. The method of claim 75, wherein the microstrip spiral inductor has an effective inductance of approximately 1.5 nH at approximately 2.4 GHz, a maximum Q factor of approximately 170 at approximately 2.4 GHz, and a self resonating frequency of approximately 8.5 GHz.

77. A method for fabricating a substrate having integrated components and adapted for use in integrated circuits, the method comprising the steps of:
fabricating a first substrate layer;
fabricating a first conductor layer on an upper surface of the first substrate layer; and
fabricating an integrated inductor on an upper surface of the first conductor layer, the integrated inductor comprising a coplanar waveguide loop inductor.

78. The method of claim 77, wherein the first substrate layer comprises an organic material.

79. The method of claim 78, wherein the organic material is at least one of an epoxy-based material and a liquid crystalline polymer.

80. The method of claim 77, wherein the step of fabricating an integrated inductor further comprises configuring the number of loops of the coplanar waveguide loop inductor to optimize at least one of a frequency for a maximum Q factor, an effective inductance, and a self resonant frequency.

81. The method of claim 77, wherein the coplanar waveguide loop inductor comprises a hollows-ground coplanar waveguide loop inductor.

82. A method for fabricating a substrate having integrated components and adapted for use in integrated circuits, the method comprising the steps of:
fabricating a first substrate layer;
fabricating a first conductor layer on an upper surface of the first substrate layer; and
fabricating an integrated inductor on an upper surface of the first conductor layer, the integrated inductor comprising a microstrip loop inductor.

83. The method of claim 82, wherein the step of fabricating an integrated inductor further comprises configuring the microstrip loop inductor to optimize at least one of a frequency for a maximum Q factor, an effective inductance, and a self resonant frequency.

84. The method of claim 82, wherein the step of fabricating an integrated inductor further comprises configuring at least one of the number of loops and the line width of the micro strip loop inductor to optimize at least one of a frequency for a maximum Q factor, an effective inductance, and a self resonant frequency.

85. The method of claim 82, wherein the microstrip loop inductor comprises a single loop having a line width of approximately 2 mils and an area of approximately 3.5 millimeters².

86. The method of claim 85, wherein the microstrip loop inductor has an effective inductance of approximately 7.7 nH, a maximum Q factor of approximately 90 at approximately 2.4 GHz, and a self resonating frequency of approximately 7.2 GHz.

87. The method of claim 82, wherein the microstrip loop inductor comprises two cascaded loops.

88. The method of claim 87, wherein the microstrip loop inductor has a line width of approximately 6 mils and an area of approximately 4.3 millimeters².

89. The method of claim 88, wherein the microstrip loop inductor has an effective inductance of approximately 7.8 nH, a maximum Q factor of approximately 110 at approximately 2.1 GHz, and a self resonating frequency of approximately 6 GHz.

90. The method of claim 87, wherein the microstrip loop inductor has a line width of approximately 4 mils and an area of approximately 3.5 millimeters².

91. The method of claim 90, wherein the micro strip loop inductor has an effective inductance of approximately 10.2 nH, a maximum Q factor of approximately 85 at approximately 2.2 GHz, and a self resonating frequency of approximately 5 GHz.

92. The method of claim 82, wherein the microstip loop inductor comprises three cascaded loops.

93. The method of claim 92, wherein the microstrip loop inductor has an area of approximately 4 millimeters² and a first portion of the micro strip loop inductor has a line width of approximately 4 mils and a second portion of the microstrip loop inductor has a line width of approximately 8 mils.

94. The method of claim 93, wherein the microstrip loop inductor has an effective inductance of approximately 15 nH, a maximum Q factor of approximately 80 at approximately 1 GHz, and a self resonating frequency of approximately 3.2 GHz.

95. The method of claim 92, wherein the microstrip loop inductor has an area of approximately 4 millimeters² and a first portion of the microstrip loop inductor has a line width of approximately 4 mils and a second portion of the microstrip loop inductor has a line width of approximately 2 mils.

96. The method of claim 95, wherein the microstrip loop inductor has an effective inductance of approximately 17 nH, a maximum Q factor of approximately 70 at approximately 1 GHz, and a self resonating frequency of approximately 3 GHz.

97. A computer program embodied in a computer-readable medium for optimizing the design of an integrated inductor in a substrate adapted for use in integrated circuits, the computer program comprising:
logic configured to receive one or more design parameters for a substrate structure in which an inductor is to be integrated, the design parameters specifying at least one of the material characteristics, the physical characteristics, and electrical characteristics of one or more substrate layers and one or more conductor layers comprising the substrate structure;
logic configured to receive one or more process parameters associated with a predetermined type of integrated circuit package in which the substrate structure is to be implemented;
logic configured to generate a coupled-line model for a plurality of configurations for an integrated inductor, the coupled-line model comprising one or more coupled lines and one or more discontinuities;
logic configured to simulate the frequency response of the coupled-line models based on the design parameters and process parameters; and logic configured to determine an optimal configuration for the integrated inductor which satisfies the design parameters and process parameters.

98. The computer program of claim 101, further comprising logic configured to provide the optimal layout for an integrated inductor.

99. The computer program of claim 97, wherein the logic configured to simulate the frequency response comprises:
segmenting the coupled-line model of the integrated inductor into individual segments;
calculating an impedance matrix for each of the segments in the coupled-line model; and
determining the frequency response of the combination of the segments.

100. The computer program of claim 99, wherein the logic configured to simulate the frequency response further comprises solving the following system of equations for each of a set of pairs of symmetric lossless coupled lines:
$$[ \begin{matrix}{V}_{1} \\ {V}_{2} \\ {V}_{3} \\ {V}_{4}\end{matrix} ] = [ \begin{matrix}{Z}_{11} & {Z}_{12} & {Z}_{13} & {Z}_{14} \\ {Z}_{21} & {Z}_{22} & {Z}_{23} & {Z}_{24} \\ {Z}_{31} & {Z}_{32} & {Z}_{33} & {Z}_{34} \\ {Z}_{41} & {Z}_{42} & {Z}_{43} & {Z}_{44}\end{matrix} ] [ \begin{matrix}{I}_{1} \\ {I}_{2} \\ {I}_{3} \\ {I}_{4}\end{matrix} ] ;$$
wherein:
V₁=voltage at a first node of a first lossless coupled line;
V₂=voltage at a first node of a second lossless coupled line;
V₃=voltage at a second node of the first lossless coupled line;
V₄=voltage at a second node of the second lossless coupled line;
l=length of coupled lines;
Zoe=even-mode impedance;
Zoo=odd-mode impedance;
βe=even-mode propogation constant;
βo=odd-mode propogation constant;
Z₁₁=Z₂₂=Z₃₃=Z₄₄=−j(Zₒₑcot(βₑl)+Zₒₒcot(βₒl))/2
Z₁₂=Z₂₁=Z₃₄=Z₄₃=−j(Zₒₑcot(βₑl)−Zₒₒcot(βₒl))/2
Z₁₃=Z₂₄=Z₃₁=Z₄₂=−j(Zₒₑcsc(βₑl)+Zₒₒcsc(βₒl))/2
Z₁₄=Z₂₃=Z₃₂=Z₄₁=−j(Zₒₑcsc(βₑl)−Zₒₒcsc(βₒl))/2.

101. The computer program of claim 97, wherein the logic configured to generate a coupled-line model is adapted to model at least one of a coplanar waveguide loop inductor, a microstrip loop inductor, and a microstrip spiral inductor.

102. The computer program of claim 97, wherein the logic configured to receive one or more design parameters for a substrate structure is further configured to receive one or more design parameters for the integrated inductor to be designed.

103. The computer program of claim 102, wherein the one or more design parameters for the integrated inductor specifies a type of integrated inductor to be designed.

104. The computer program of claim 103, wherein the type of integrated inductor comprises one of a coplanar waveguide loop inductor, a microstrip loop inductor, and a microstrip spiral inductor.

105. The computer program of claim 102, wherein the one or more design parameters for the integrated inductor comprises at least one of a predetermined line width for the integrated inductor, a predetermined line spacing for the integrated inductor, a predetermined maximum area for the integrated inductor, a predetermined inductance value for the integrated inductor, a predetermined frequency, a predetermined minimum Q factor for the integrated inductor, and a predetermined self resonant frequency for the integrated inductor.

106. A system for optimizing the design of an integrated inductor in a substrate adapted for use in integrated circuits, the system comprising:
means for receiving one or more design parameters for a substrate structure in which an inductor is to be integrated and one or more process parameters associated with a predetermined type of integrated circuit package in which the substrate structure is to be implemented, the design parameters specifying at least one of the material characteristics, the physical characteristics, and electrical characteristics of one or more substrate layers and one or more conductor layers comprising the substrate structure;
means for generating a coupled-line model for a plurality of configurations for an integrated inductor, the coupled-line model comprising one or more coupled lines and one or more discontinuities;
means for simulating the frequency response of the coupled-line models based on the design parameters and process parameters; and
means for determining an optimal configuration for the integrated inductor which satisfies the design parameters and process parameters.

107. The system of claim 106, further comprising a means for providing the optimal layout for an integrated inductor.

108. The system of claim 106, wherein means for simulating comprises:
means for segmenting the coupled-line model of the integrated inductor into individual segments;
means for calculating an impedance matrix for each of the segments in the coupled-line model; and
means for determining the frequency response of the combination of the segments.

109. The system of claim 108, wherein the means for simulating further comprises a means for solving the following system of equations for each of a set of pairs of symmetric lossless coupled lines:
$$[ \begin{matrix}{V}_{1} \\ {V}_{2} \\ {V}_{3} \\ {V}_{4}\end{matrix} ] = [ \begin{matrix}{Z}_{11} & {Z}_{12} & {Z}_{13} & {Z}_{14} \\ {Z}_{21} & {Z}_{22} & {Z}_{23} & {Z}_{24} \\ {Z}_{31} & {Z}_{32} & {Z}_{33} & {Z}_{34} \\ {Z}_{41} & {Z}_{42} & {Z}_{43} & {Z}_{44}\end{matrix} ] [ \begin{matrix}{I}_{1} \\ {I}_{2} \\ {I}_{3} \\ {I}_{4}\end{matrix} ] ;$$
wherein:
V₁=voltage at a first node of a first lossless coupled line;
V₂=voltage at a first node of a second lossless coupled line;
V₃=voltage at a second node of the first lossless coupled line;
V₄=voltage at a second node of the second lossless coupled line;
l=length of coupled lines;
Zoe=even-mode impedance;
Zoo=odd-mode impedance;
βe=even-mode propogation constant;
βo=odd-mode propogation constant;
Z₁₁=Z₂₂=Z₃₃=Z₄₄=−j(Zₒₑcot(βₑl)+Zₒₒcot(βₒl))/2
Z₁₂=Z₂₁=Z₃₄=Z₄₃=−j(Zₒₑcot(βₑl)−Zₒₒcot(βₒl))/2
Z₁₃=Z₂₄=Z₃₁=Z₄₂=−j(Zₒₑcsc(βₑl)+Zₒₒcsc(βₒl))/2
Z₁₄=Z₂₃=Z₃₂=Z₄₁=−j(Zₒₑcsc(βₑl)−Zₒₒcsc(βₒl))/2.

110. The system of claim 106, wherein the means for generating a coupled-line model is adapted to model at least one of a coplanar waveguide loop inductor, a microstrip loop inductor, and a microstrip spiral inductor.

111. The system of claim 106, wherein the means for receiving further receives one or more design parameters for the integrated inductor to be designed.

112. The system of claim 106, wherein the one or more design parameters for the integrated inductor specify a type of integrated inductor to be designed.

113. The system of claim 112, wherein the type of integrated inductor comprises one of a coplanar waveguide loop inductor, a microstrip loop inductor, and a microstrip spiral inductor.

114. The computer program of claim 111, wherein the one or more design parameters for the integrated inductor comprises at least one of a predetermined line width for the integrated inductor, a predetermined line spacing for the integrated inductor, a predetermined maximum area for the integrated inductor, a predetermined inductance value for the integrated inductor, a predetermined frequency, a predetermined minimum Q factor for the integrated inductor, and a predetermined self resonant frequency for the integrated inductor.

115. A system for optimizing the design of an integrated inductor in a substrate adapted for use in integrated circuits, the system comprising:
logic configured to receive one or more design parameters for a substrate structure in which an inductor is to be integrated, the design parameters specifying at least one of the material characteristics, the physical characteristics, and electrical characteristics of one or more substrate layers and one or more conductor layers comprising the substrate structure;
logic configured to receive one or more process parameters associated with a predetermined type of integrated circuit package in which the substrate structure is to be implemented;
logic configured to generate a coupled-line model for a plurality of configurations for an integrated inductor, the coupled-line model comprising one or more coupled lines and one or more discontinuities;
logic configured to simulate the frequency response of the coupled-line models based on the design parameters and process parameters;
logic configured to determine an optimal configuration for the integrated inductor which satisfies the design parameters and process parameters; and
a processing device configured to implement the logic.

116. The system of claim 115, further comprising a user interface device configured to enable a user to input the design parameters and the process parameters.

117. The system of claim 115, further comprising logic configured to provide the optimal layout for an integrated inductor.

118. The system of claim 117, further comprising a display device configured to display the optimal layout.

119. The system of claim 115, wherein the logic configured to simulate the frequency response comprises:
segmenting the coupled-line model of the integrated inductor into individual segments;
calculating an impedance matrix for each of the segments in the coupled-line model; and
determining the frequency response of the combination of the segments.

120. The system of claim 115, wherein the logic configured to simulate the frequency response further comprises solving the following system of equations for each of a set of pairs of symmetric lossless coupled lines:
$$[ \begin{matrix}{V}_{1} \\ {V}_{2} \\ {V}_{3} \\ {V}_{4}\end{matrix} ] = [ \begin{matrix}{Z}_{11} & {Z}_{12} & {Z}_{13} & {Z}_{14} \\ {Z}_{21} & {Z}_{22} & {Z}_{23} & {Z}_{24} \\ {Z}_{31} & {Z}_{32} & {Z}_{33} & {Z}_{34} \\ {Z}_{41} & {Z}_{42} & {Z}_{43} & {Z}_{44}\end{matrix} ] [ \begin{matrix}{I}_{1} \\ {I}_{2} \\ {I}_{3} \\ {I}_{4}\end{matrix} ] ;$$
wherein:
V₁=voltage at a first node of a first lossless coupled line;
V₂=voltage at a first node of a second lossless coupled line;
V₃=voltage at a second node of the first lossless coupled line;
V₄=voltage at a second node of the second lossless coupled line;
l=length of coupled lines;
Zoe=even-mode impedance;
Zoo=odd-mode impedance;
βe=even-mode propagation constant;
βo=odd-mode propogation constant;
Z₁₁=Z₂₂=Z₃₃=Z₄₄=−j(Zₒₑcot(βₑl)+Zₒₒcot(βₒl))/2
Z₁₂=Z₂₁=Z₃₄=Z₄₃=−j(Zₒₑcot(βₑl)−Zₒₒcot(βₒl))/2
Z₁₃=Z₂₄=Z₃₁=Z₄₂=−j(Zₒₑcsc(βₑl)+Zₒₒcsc(βₒl))/2
Z₁₄=Z₂₃=Z₃₂=Z₄₁=−j(Zₒₑcot(βₑl)−Zₒₒcsc(βₒl))/2.

121. The system of claim 115, wherein the logic configured to generate a coupled-line model is adapted to model at least one of a coplanar waveguide loop inductor, a microstrip loop inductor, and a microstrip spiral inductor.

122. The system of claim 115, wherein the logic configured to receive one or more design parameters for a substrate structure is further configured to receive one or more design parameters for the integrated inductor to be designed.

123. The system of claim 122, wherein the one or more design parameters for the integrated inductor specifies a type of integrated inductor to be designed.

124. The system of claim 123, wherein the type of integrated inductor comprises one of a coplanar waveguide loop inductor, a microstrip loop inductor, and a microstrip spiral inductor.

125. The system of claim 122, wherein the one or more design parameters for the integrated inductor comprises at least one of a predetermined line width for the integrated inductor, a predetermined line spacing for the integrated inductor, a predetermined maximum area for the integrated inductor, a predetermined inductance value for the integrated inductor, a predetermined frequency, a predetermined minimum Q factor for the integrated inductor, and a predetermined self resonant frequency for the integrated inductor.
